(19) United States
(12) Patent Application Publication
(10) Pub. No.: US 2026/0140442 A1
(43) Pub. Date: May 21, 2026

(54) RADIATION SENSITIVE RESIN COMPOSITION AND PATTERN FORMATION METHOD

(71) Applicant: JSR CORPORATION, Tokyo (JP)

(72) Inventors: Katsuaki NISHIKORI, Tokyo (JP); Atsushi KOBAYASHI, Tokyo (JP); Asuka HACHIYA, Tokyo (JP); Motohiro SHIRATANI, Tokyo (JP); Ryuichi NEMOTO, Tokyo (JP)

(73) Assignee: JSR CORPORATION, Tokyo (JP)

(21) Appl. No.: 19/120,452

(22) PCT Filed: Sep. 27, 2023
(86) PCT No.: PCT/JP2023/035159

§ 371 Date: Apr. 11, 2025

(30) Foreign Application Priority Data
Nov. 15, 2022 (JP) 2022-182646

(51) Int. Cl. G03F 7/004; G03F 7/00; G03F 7/039

(52) U.S. Cl. CPC G03F 7/0045; G03F 7/039; G03F 7/70033

(57) ABSTRACT

A radiation-sensitive resin composition includes: a radiation-sensitive onium salt (A) represented by formula (1); a radiation-sensitive onium salt (B) different from the radiation-sensitive onium salt (A) and represented by formula (2); a resin including a structural unit which includes an acid-dissociable group; and a solvent. R^{p1} is a substituted or unsubstituted (nₚ+1)-valent hydrocarbon group having 1 to 20 carbon atoms, or a group including a divalent heteroatom-containing structure between adjacent two carbon atoms of a substituted or unsubstituted (nₚ+1)-valent hydrocarbon group having 1 to 20 carbon atoms, nₚ is an integer of 1 to 5, and X₁⁺ is a monovalent radiation-sensitive onium cation. R^{p2} is a substituted or unsubstituted monovalent hydrocarbon group having 1 to 20 carbon atoms, and X₂⁺ is a monovalent radiation-sensitive onium cation. At least one of X₁⁺ and X₂⁺ is a cation including a fluorine atom.

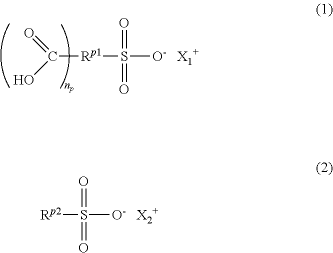

### TECHNICAL FIELD

The present disclosure relates to a radiation-sensitive resin composition and a pattern formation method.

### BACKGROUND ART

A photolithography technology has been utilized in which a resist composition is used for the formation of a fine circuit on a semiconductor device. As a representative procedure, for example, a resist pattern is formed on a substrate by generating an acid by irradiating a coating film of the resist composition with radiation through a mask pattern, followed by a reaction in the presence of the acid as a catalyst to generate a difference in solubility of a resin into an alkaline or organic solvent-based developer between an exposed area and an unexposed area.

In the photolithography technique, pattern miniaturization is promoted by using short-wavelength radiation such as ArF excimer laser, or by combining such radiation with an immersion exposure method (liquid immersion lithography). As the next generation technology, a shorter-wavelength radiation, such as an electron beam, an X-ray, and an extreme ultraviolet ray (EUV) is being utilized, and a resist material containing an acid generator with a fluorine-substituted benzene ring having an enhanced efficiency of absorbing such a radiation is also being studied. (Patent Document 1).

### PRIOR ART DOCUMENT

### Patent Document

Patent Document 1: JP-A-2014-2359

### SUMMARY OF THE INVENTION

### Problems to be Solved by the Invention

However, it has been found that the storage stability of the resist composition is deteriorated when the technique for improving the efficiency of absorbing radiation is applied.

An object of the present invention is to provide a radiation-sensitive resin composition that has good storage stability and is capable of forming a resist film having superior sensitivity and critical dimension uniformity (CDU) performance when the next generation technology is applied, and a pattern formation method.

### Means for Solving the Problems

In order to achieve the object, the present inventors have intensively studied, and as a result have found that the object can be achieved by employing the following features. This finding has led to the completion of the present invention.

The present invention relates, in one embodiment, to
a radiation-sensitive resin composition including:
a radiation-sensitive onium salt (A) represented by the following formula (1),

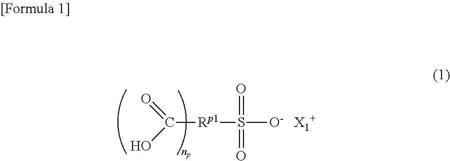

in the formula (1),
R^{p1} is a substituted or unsubstituted (nₚ+1)-valent hydrocarbon group having 1 to 20 carbon atoms, or a group containing a (divalent heteroatom)-containing structure between adjacent two carbon atoms of the hydrocarbon group,
nₚ is an integer of 1 to 5, and
X₁⁺ is a monovalent radiation-sensitive onium cation;
a radiation-sensitive onium salt (B) that is different from the radiation-sensitive onium salt (A) and is represented by the following formula (2),

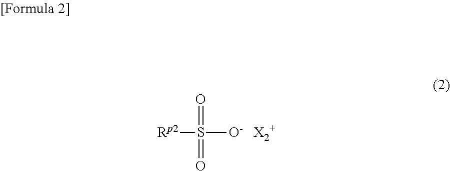

in the formula (2),
R^{p2} is a substituted or unsubstituted monovalent hydrocarbon group having 1 to 20 carbon atoms, and
X₂⁺ is a monovalent radiation-sensitive onium cation;
a resin containing a structural unit having an acid-dissociable group; and
a solvent,
wherein at least one of X₁⁺ and X₂⁺ is a cation containing a fluorine atom.

The radiation-sensitive resin composition has good storage stability, and can construct a resist film satisfying sensitivity and CDU performance. The reason for this is not clear, but can be expected as follows. Due to the fluorine-containing onium cation moiety of the onium salt, the absorption of radiation such as EUV having a wavelength of 13.5 nm by fluorine atoms becomes very large, and the secondary electron generation efficiency also increases, so that the radiation-sensitive resin composition is made highly sensitive.

Meanwhile, for example, in a system in which a salicylic acid anion, which has heretofore been frequently used, is simply applied as an organic acid anion moiety, the storage stability may be deteriorated by introduction of the fluorine-containing onium cation moiety. As a result of examining the cause of this phenomenon, the present inventors have considered that because of high electrophilicity of the fluorine-containing onium cation, the fluorine-containing onium cation is likely to be decomposed when used in combination with a highly basic organic acid anion, so that storage stability is deteriorated. In contrast to this, it is presumed that thanks to adoption of the configuration involving the presence of the radiation-sensitive onium salt (A) represented by the above formula (1) and the radiation-sensitive onium salt (B) represented by the above formula (2), which is different from the radiation-sensitive onium salt (A), it is possible to suppress the decomposition of the fluorine-containing onium cation moiety to exhibit good storage stability.

In another embodiment, the present invention relates to
a pattern formation method, the method comprising:
a step of directly or indirectly applying the radiation-sensitive resin composition on a substrate to form a resist film,
a step of exposing the resist film to light, and
a step of developing the exposed resist film with a developer.

In the pattern formation method, since a radiation-sensitive resin composition that has good storage stability and is capable of forming a resist film having superior sensitivity and CDU performance is used, a high-quality resist pattern can be efficiently formed.

### MODE FOR CARRYING OUT THE INVENTION

Hereinbelow, embodiments of the present invention will specifically be described, but the present invention is not limited to these embodiments.

### <<Radiation-Sensitive Resin Composition>>

The radiation-sensitive resin composition (hereinafter, also simply referred to as “composition”) according to the present embodiment includes one or two or more onium salts, a resin, and a solvent. The composition may contain another optional component as long as the effects of the present invention are not impaired. Owing to the fact that the radiation-sensitive resin composition includes a prescribed onium salt, the radiation-sensitive resin composition can exhibit good storage stability, and can impart high level of sensitivity and CDU performance to a resist film to be obtained.

### <Onium Salt>

The onium salt is a component that contains an organic acid anion moiety and an onium cation moiety and generates an acid through exposure to light. Since at least a part of the onium cation moiety in the onium salt is a fluorine-containing onium cation moiety containing a fluorine atom, high sensitivity can be achieved by improving the radiation absorption efficiency (and secondary electron generation efficiency) and then improving the acid generation efficiency.

While the mode of inclusion of the onium salt in the radiation-sensitive resin composition is not particularly limited, the onium salt is preferably at least one member selected from the group consisting of a radiation-sensitive acid generator containing the organic acid anion moiety and an acid diffusion controlling agent containing the organic acid anion moiety and the onium cation moiety and being to generate an acid having a pKa higher than that of an acid to be generated from the radiation-sensitive acid generator through irradiation with radiation. These respective functions will be described below.

The acid generated through the exposure of the onium salt to light is considered to have two functions in the radiation-sensitive resin composition depending on the strength of the acid. Examples of the first function include a function to cause the acid generated through the exposure to dissociate an acid-dissociable group of a structural unit when the resin contains the structural unit having the acid-dissociable group, and generate a carboxy group or the like. An onium salt having the first function is referred to as a radiation-sensitive acid generator. The second function includes a function to suppress, by salt exchange, the diffusion of the acid generated from the radiation-sensitive acid generator in an unexposed area substantially without dissociating the acid-dissociable group of the resin under a pattern formation condition with use of the radiation-sensitive resin composition. An onium salt having the second function is referred to as an acid diffusion controlling agent. The acid generated from the radiation-sensitive acid generator can be said to be a relatively stronger acid (acid having a lower pKa) than the acid generated from the acid diffusion controlling agent. Whether an onium salt functions as a radiation-sensitive acid generator or an acid diffusion controlling agent depends on the energy required for dissociating the acid-dissociable group of the resin, the acidity of the onium salt, and the like. The mode of inclusion of the radiation-sensitive acid generator in the radiation-sensitive resin composition is preferably a mode in which the onium salt structure is present alone as a (low molecular weight) compound.

Owing to the fact that the radiation-sensitive resin composition includes the radiation-sensitive acid generator, the polarity of the resin in an exposed area increases, and as a result, when the developer is an aqueous alkaline solution, the resin in the exposed area is soluble in the developer, whereas when the developer is an organic solvent, the resin in the exposed area is hardly soluble in the developer.

In addition, owing to the fact that the radiation-sensitive resin composition includes the acid diffusion controlling agent, diffusion of an acid in an unexposed area can be controlled, and a resist pattern further superior in pattern developability and CDU performance can be formed.

In the present embodiment, at least one of the onium cation moieties in the radiation-sensitive onium salt (A) and the radiation-sensitive onium salt (B) as the radiation-sensitive acid generator described above is a fluorine-containing onium cation moiety. It is preferable that both the onium cation moieties in the radiation-sensitive acid generators be the fluorine-containing onium cation moieties.

The mode in which the fluorine atom is contained in the fluorine-containing onium cation moiety is not particularly limited, but the fluorine-containing onium cation moiety preferably contains an aromatic ring structure having a fluorine atom (hereinafter, also referred to as a “fluorine-substituted aromatic ring structure”). By combining a fluorine atom, which is electron-withdrawing, with an aromatic ring structure, further improvement in radiation absorption efficiency can be expected. The “aromatic ring structure having a fluorine atom” includes not only a structure in which the fluorine atom is directly bonded to the aromatic ring structure but also a structure in which the fluorine atom is bonded to the aromatic ring structure via another atom (for example, a structure in which the fluorine atom is bonded to a substituent bonded to the aromatic ring structure).

### <Radiation-Sensitive Acid Generator>

The radiation-sensitive resin composition includes a radiation-sensitive acid generator that generates an acid having a lower pKa than that of the acid generated from the acid diffusion controlling agent through irradiation with radiation (exposure to light). Owing to the fact that the radiation-sensitive resin composition includes the radiation-sensitive acid generator, the acid generated through exposure to light dissociates the acid-dissociable group of the resin to generate a carboxy group or the like. As a result, the polarity of the resin in an exposed area increases, so that in development with an aqueous alkaline solution, the resin on the exposed area is soluble in the developer, whereas in development with an organic solvent, the resin in an exposed area is hardly soluble in the developer.

The radiation-sensitive acid generator is preferably a radiation-sensitive onium salt containing an organic acid anion moiety and an onium cation moiety. The organic acid anion moiety preferably has at least one selected from the group consisting of a sulfonate anion and a sulfonimide anion. Examples of the acid generated through exposure to light include a sulfonic acid and a sulfonimide corresponding to the organic acid anion moiety. The organic acid anion moiety preferably contains an iodine-substituted aromatic ring structure.

The radiation-sensitive resin composition includes the radiation-sensitive onium salt (A) and the radiation-sensitive onium salt (B) as radiation-sensitive acid generators.

### <Radiation-Sensitive Onium Salt (A)>

The radiation-sensitive onium salt (A) (hereinafter, also referred to as “photoacid generator [A]”) is represented by the following formula (1).

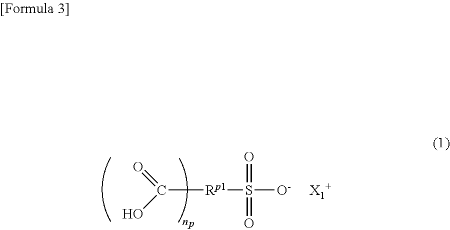

In the formula (1), R^{p1} is a substituted or unsubstituted (nₚ+1)-valent hydrocarbon group having 1 to 20 carbon atoms or a group containing a (divalent heteroatom)-containing structure between adjacent two carbon atoms of the aforementioned hydrocarbon group.

Examples of the substituted or unsubstituted (nₚ+1)-valent hydrocarbon group having 1 to 20 carbon atoms represented by R^{p1} include a substituted or unsubstituted, linear or branched alkyl group having 1 to 20 carbon atoms and a substituted or unsubstituted aromatic hydrocarbon group having 6 to 20 carbon atoms.

As the substituted or unsubstituted, linear or branched alkyl group having 1 to 20 carbon atoms represented by R^{p1}, alkyl groups having 1 to 20 carbon atoms or cycloalkyl groups having 3 to 20 carbon atoms are preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

As the substituted or unsubstituted aromatic hydrocarbon group having 6 to 20 carbon atoms represented by R^{p1}, aryl groups having 6 to 20 carbon atoms are preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

Examples of the group containing a (divalent heteroatom)-containing structure between adjacent two carbon atoms of the substituted or unsubstituted (nₚ+1)-valent hydrocarbon group having 1 to 20 carbon atoms represented by R^{p1} include a group containing a (divalent heteroatom)-containing structure between carbon and carbon of the aforementioned substituted or unsubstituted (nₚ+1)-valent hydrocarbon group having 1 to 20 carbon atoms. Examples of the divalent heteroatom include a nitrogen atom, an oxygen atom, and a sulfur atom.

In the above formula (1), nₚ is an integer of 1 to 5. nₚ may be 2, 3, or 4 depending on the intended purpose of use or the intended application.

In the above formula (1), X₁⁺ is a monovalent radiation-sensitive onium cation.

The radiation-sensitive onium cation represented by X₁⁺ is preferably, for example, a cation represented by the following formula (3). In addition, at least one of X₁⁺ and X₂⁺ is preferably represented by the following formula (3). At least one of X₁⁺ and X₂⁺ preferably contains four or more fluorine atoms.

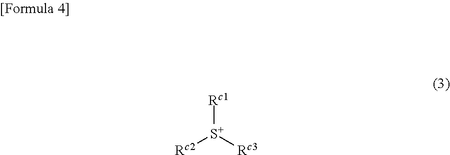

In the formula (3), R^{c1} to R^{c3} are each independently a substituted or unsubstituted, linear or branched alkyl group having 1 to 12 carbon atoms, or a substituted or unsubstituted aromatic hydrocarbon group having 6 to 12 carbon atoms. At least one among R^{c1} to R^{c3} preferably contains a fluorine atom or a trifluoromethyl group.

As the linear or branched alkyl group having 1 to 12 carbon atoms represented by R^{c1} to R^{c3}, alkyl groups having 1 to 12 carbon atoms or cycloalkyl groups having 3 to 12 carbon atoms are preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

As the substituted or unsubstituted aromatic hydrocarbon group having 6 to 12 carbon atoms represented by R^{c1} to R^{c3}, aryl groups having 6 to 12 carbon atoms are preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

Examples of the embodiment in which X₁⁺ and X₂⁺ each contain four or more fluorine atoms include an embodiment in which two or three among R^{c1} to R^{c3} are trifluoromethylphenyl groups; an embodiment in which R^{c1} is a trifluoromethylphenyl group or a trifluorophenyl group, and one or two of R^{c2} to R^{c3} are a fluorophenyl group, a difluorophenyl group, or a trifluorophenyl group; an embodiment in which two or three among R^{c1} to R^{c3} are difluorophenyl groups; and an embodiment in which Rol is a difluorophenyl group, and R^{c2} and R^{c3} are fluorophenyl groups. Substitution positions of the fluoro group and the trifluoromethyl group in the trifluoromethylphenyl group, the fluorophenyl group, the difluorophenyl group, and the trifluorophenyl group are arbitrary.

The radiation-sensitive onium salt (A) preferably contains an iodine atom. More specifically, the monovalent organic group represented by R^{cα} is preferably a monovalent organic group having 1 to 40 carbon atoms and containing 1 to 6 iodine atoms, and more preferably a monovalent organic group having 6 to 40 carbon atoms and containing a monovalent aromatic hydrocarbon group having 6 to 20 carbon atoms and substituted with 1 to 3 iodine atoms.

Examples of the cation moiety represented by the formula (1) include, but are not limited to, those shown below.

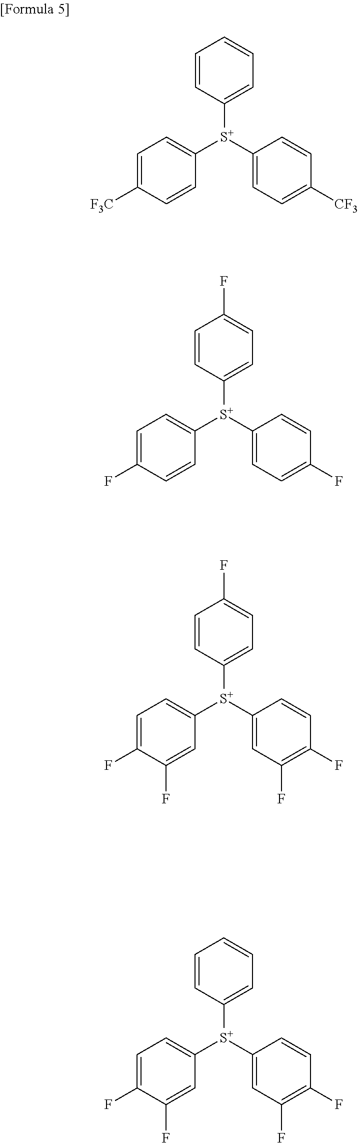 [SMILES: FC(F)(F)c1ccc([S+](c2ccccc2)c2ccc(C(F)(F)F)cc2)cc1 ; Fc1ccc([S+](c2ccc(F)cc2)c2ccc(F)cc2)cc1 ; Fc1ccc([S+](c2ccc(F)c(F)c2)c2ccc(F)c(F)c2)cc1 ; Fc1ccc([S+](c2ccccc2)c2ccc(F)c(F)c2)cc1F]

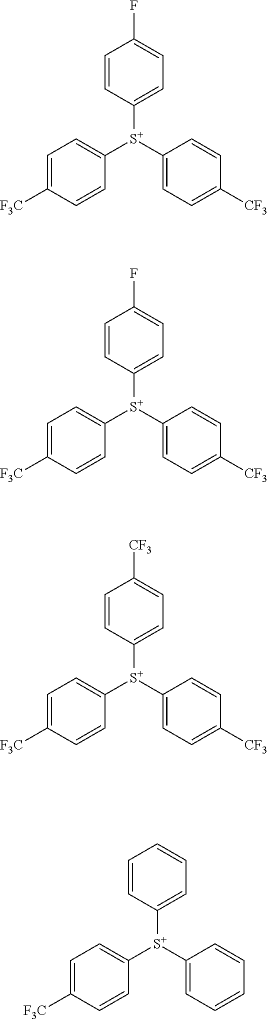 [SMILES: Fc1ccc([S+](c2ccc(C(F)(F)F)cc2)c2ccc(C(F)(F)F)cc2)cc1 ; Fc1ccc([S+](c2ccc(C(F)(F)F)cc2)c2ccc(C(F)(F)F)cc2)cc1 ; FC(F)(F)c1ccc([S+](c2ccc(C(F)(F)F)cc2)c2ccc(C(F)(F)F)cc2)cc1 ; FC(F)(F)c1ccc([S+](c2ccccc2)c2ccccc2)cc1]

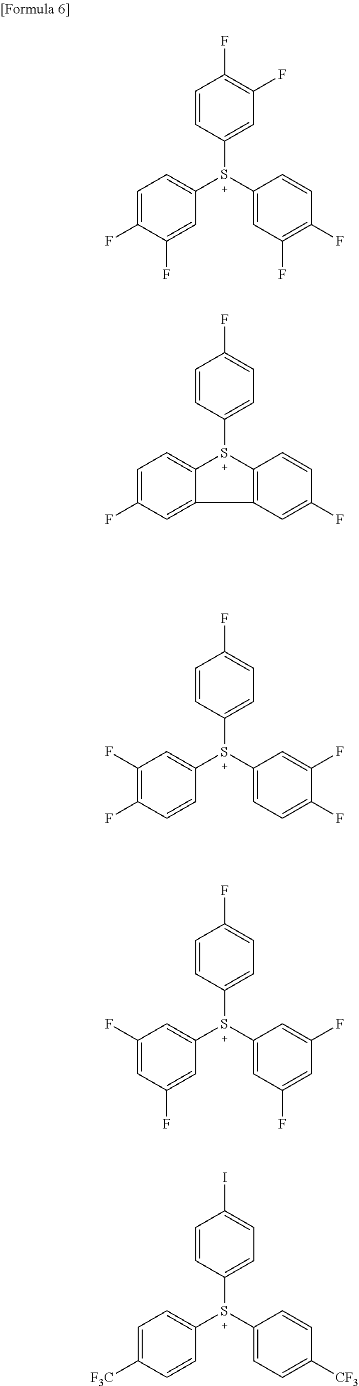

Examples of the organic acid anion moiety of the radiation-sensitive onium salt (A) represented by the formula (1) include, but are not limited to, those shown below.

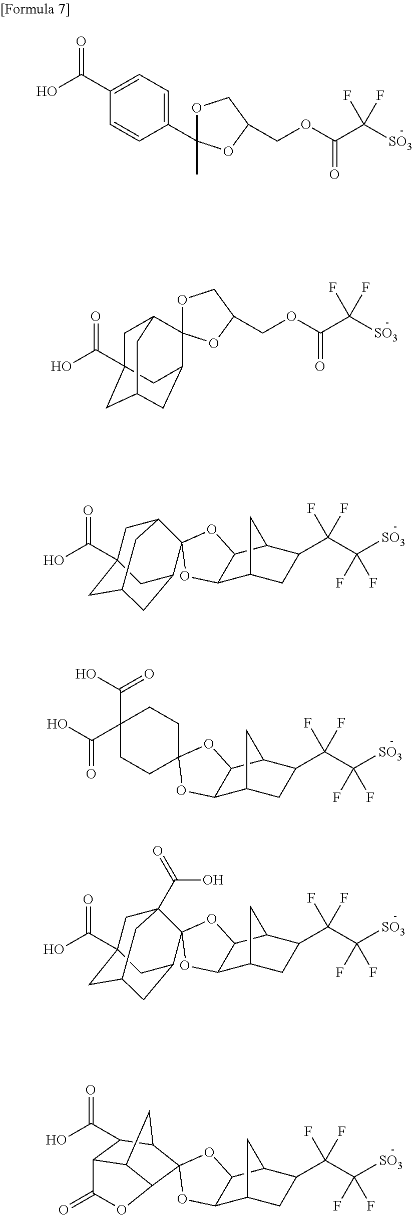

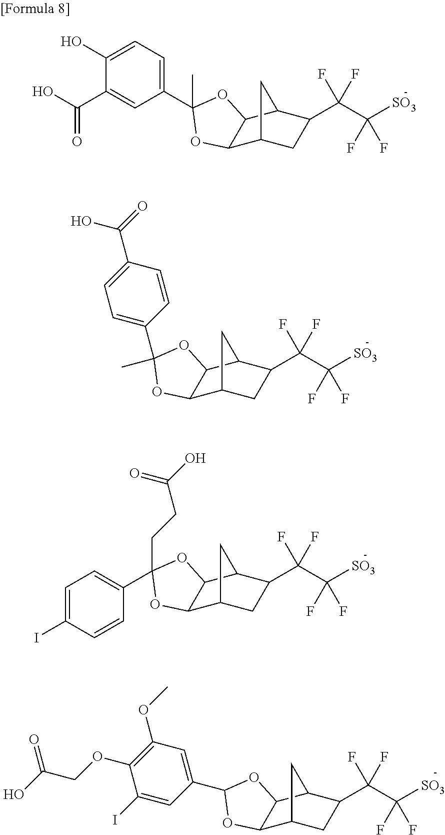

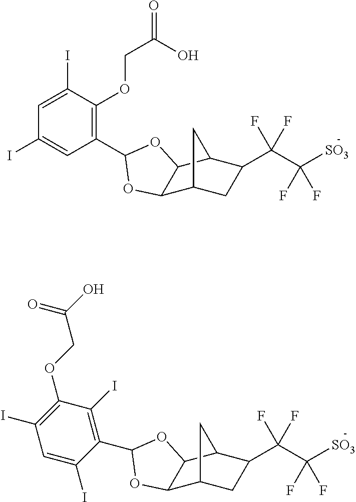

Examples of the radiation-sensitive onium salt (A) represented by the formula (1) include, but are not limited to, compounds represented by the following (A-1) to (A-12).

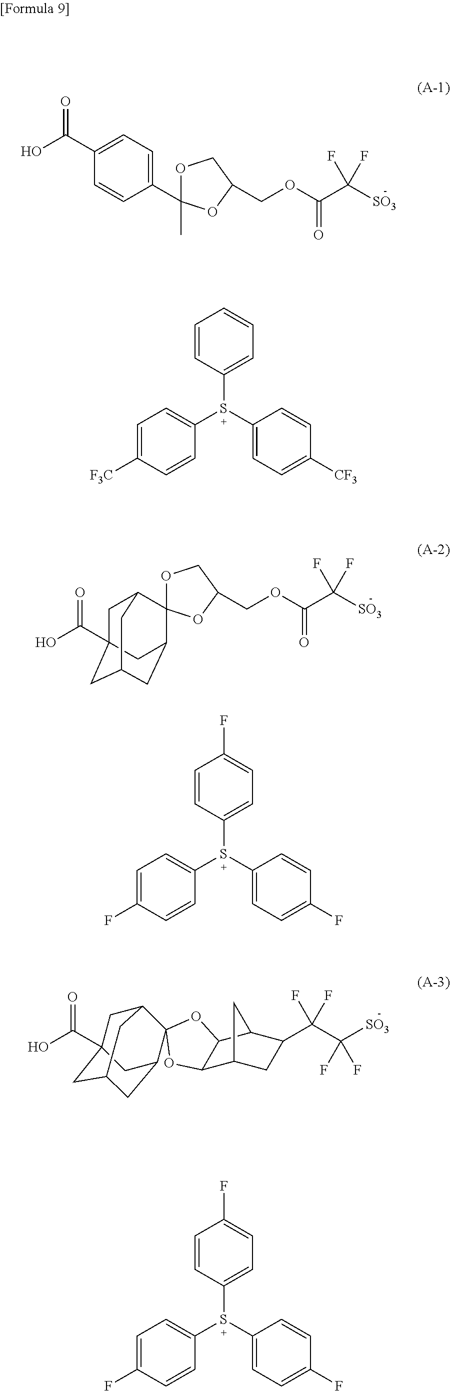

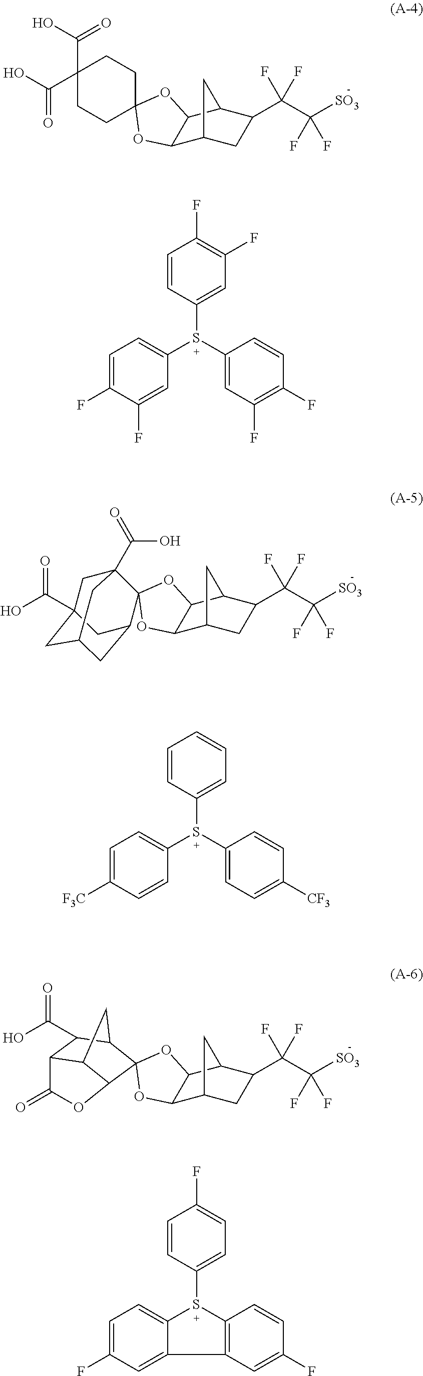

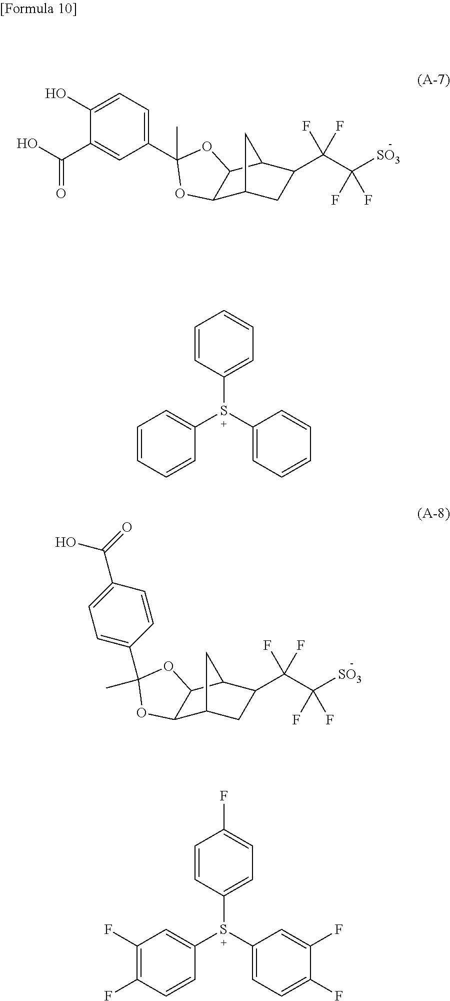

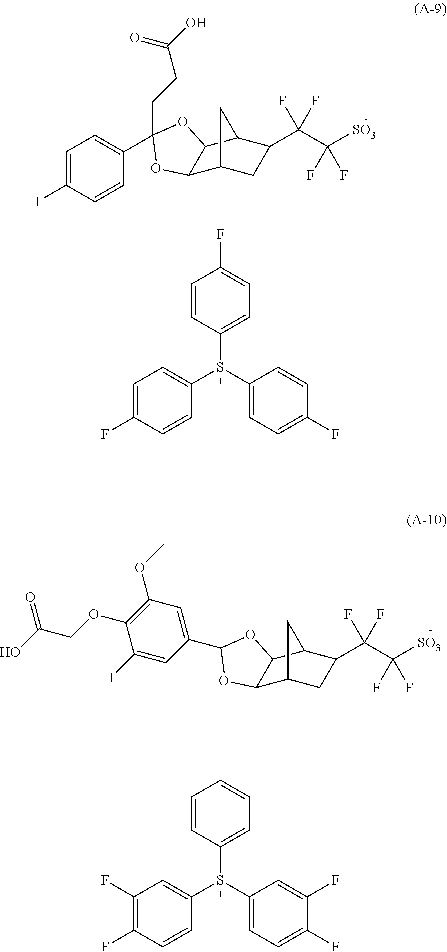

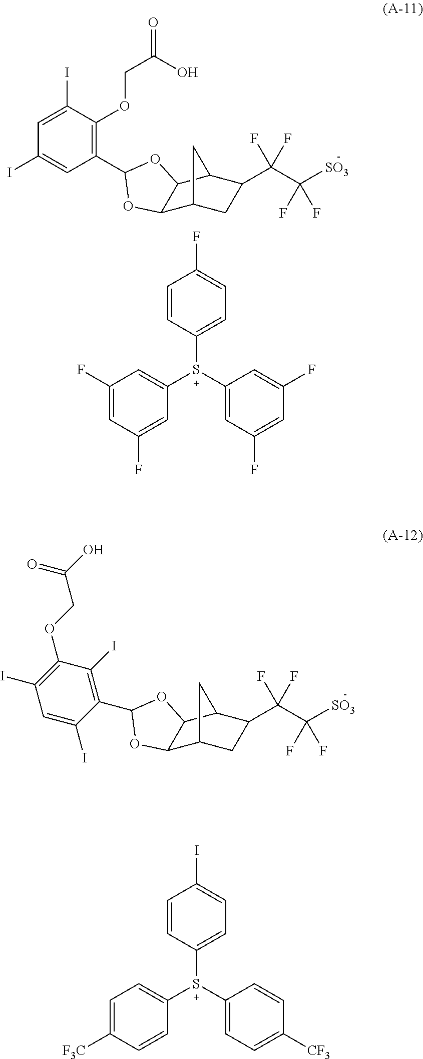

These radiation-sensitive onium salts (A) may be used singly, or two or more thereof may be used in combination. For example, the content of the radiation-sensitive onium salt (A) is 5 parts by mass or more and 45 parts by mass or less based on 100 parts by mass of the resin. The lower limit of the content of the radiation-sensitive acid generator is preferably 1 part by mass, more preferably 3 parts by mass, still more preferably 5 parts by mass, and particularly preferably 8 parts by mass based on 100 parts by mass of the resin. The upper limit of the content is preferably 60 parts by mass or less, more preferably 35 parts by mass or less, still more preferably 23 parts by mass or less, and particularly preferably 45 parts by mass or less based on 100 parts by mass of the resin. This makes it possible to exhibit superior sensitivity or CDU performance when forming a resist pattern.

### <Radiation-Sensitive Onium Salt (B)>

Unlike the radiation-sensitive onium salt (A), the radiation-sensitive onium salt (B) (hereinafter, also referred to as “photoacid generator [B]”) is represented by the following formula (2). The radiation-sensitive onium salt (B) may not contain a carboxyl group.

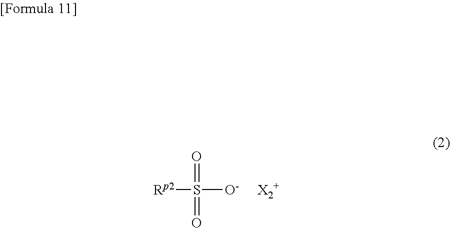

In the formula (2), R^{p2} is a substituted or unsubstituted monovalent hydrocarbon group having 1 to 20 carbon atoms.

Examples of the substituted or unsubstituted monovalent hydrocarbon group having 1 to 20 carbon atoms represented by R^{p2} include a substituted or unsubstituted, linear or branched alkyl group having 1 to 20 carbon atoms and a substituted or unsubstituted aromatic hydrocarbon group having 6 to 20 carbon atoms.

As the substituted or unsubstituted, linear or branched alkyl group having 1 to 20 carbon atoms represented by R^{p2}, alkyl groups having 1 to 20 carbon atoms or cycloalkyl groups having 3 to 20 carbon atoms are preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

As the substituted or unsubstituted aromatic hydrocarbon group having 6 to 20 carbon atoms represented by R^{p2}, aryl groups having 6 to 20 carbon atoms are preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

In the above formula (2), X₂⁺ is a monovalent radiation-sensitive onium cation.

The radiation-sensitive onium cation represented by X₂⁺ is preferably, for example, a cation represented by the above formula (3).

Examples of the organic acid anion moiety of the radiation-sensitive onium salt (B) represented by the formula (2) include, but are not limited to, those shown below.

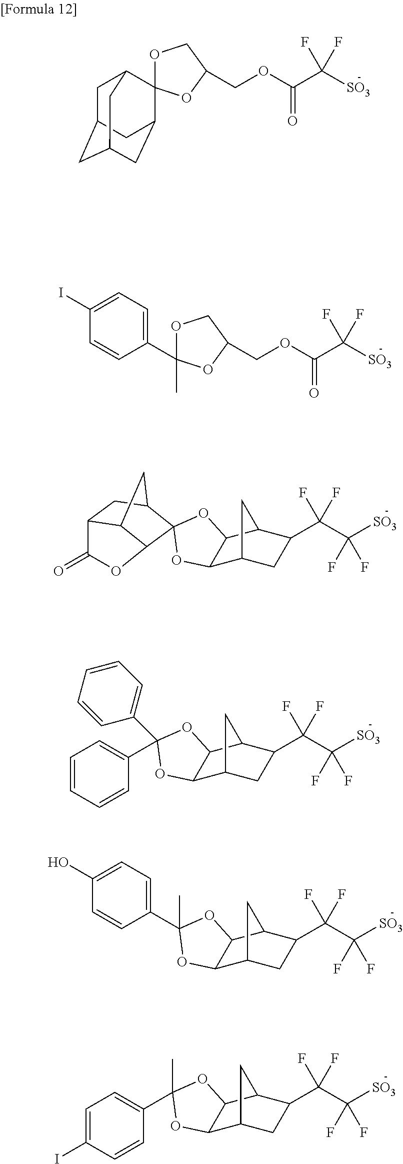

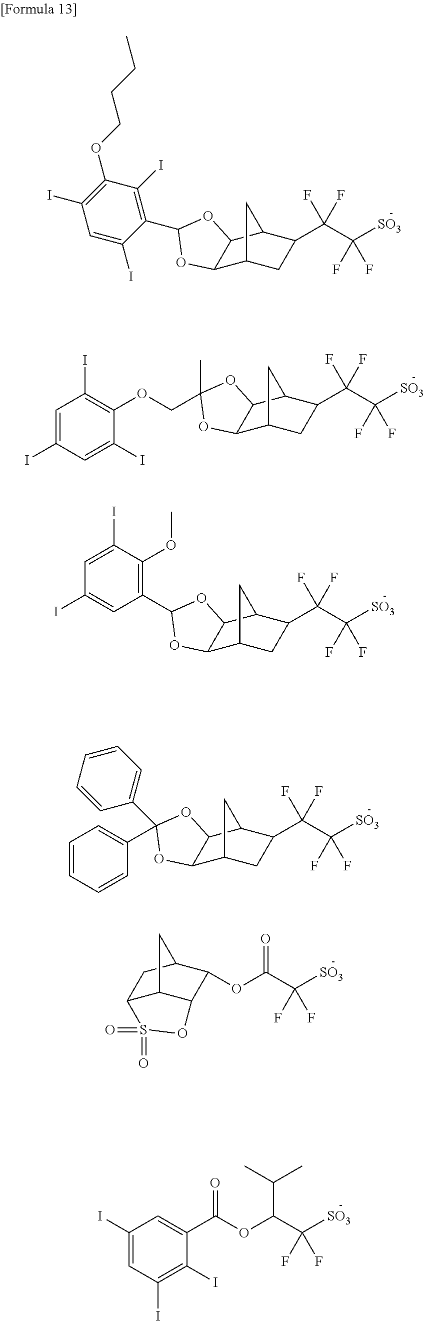

Examples of the radiation-sensitive onium salt (B) represented by the formula (2) include, but are not limited to, compounds represented by the following (B-1) to (B-12).

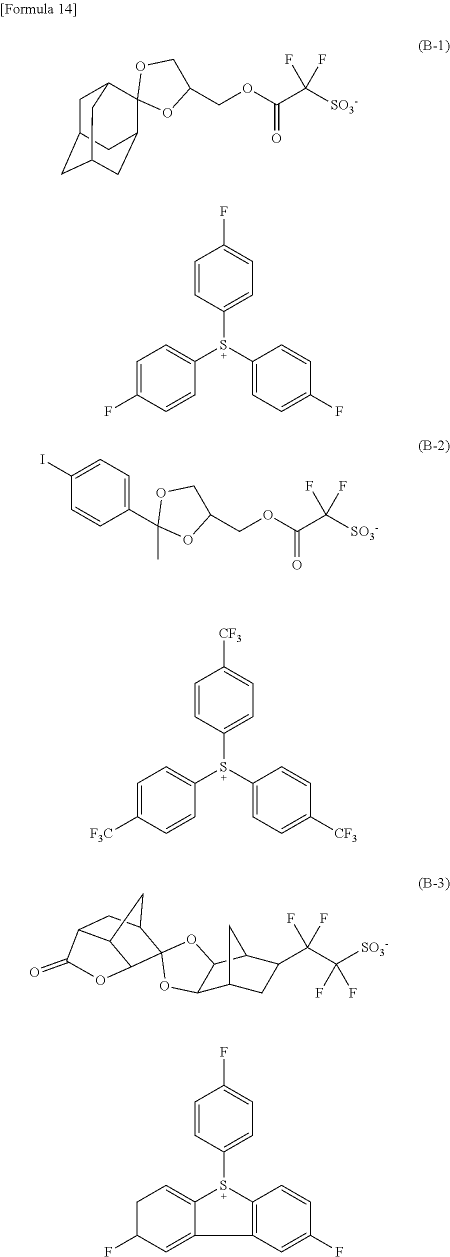

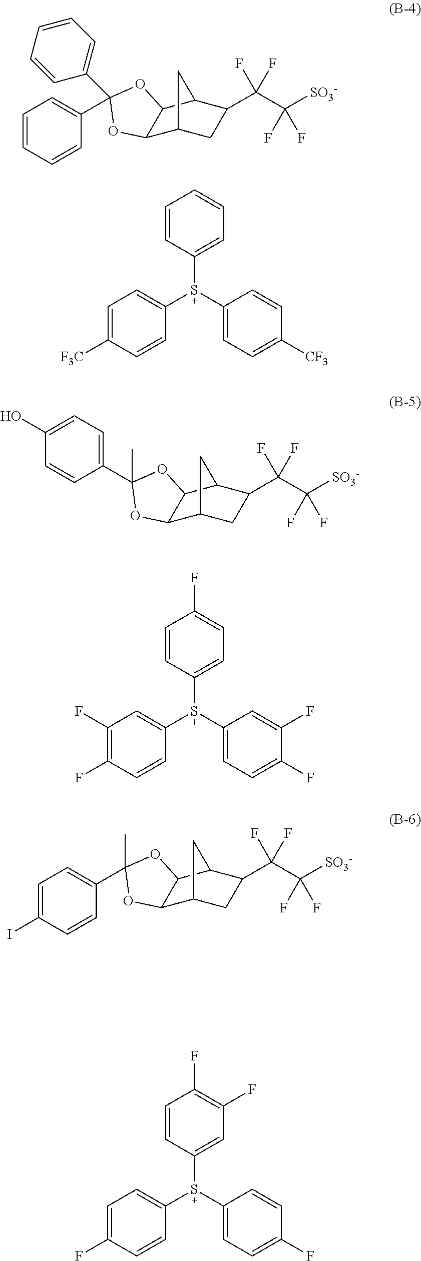

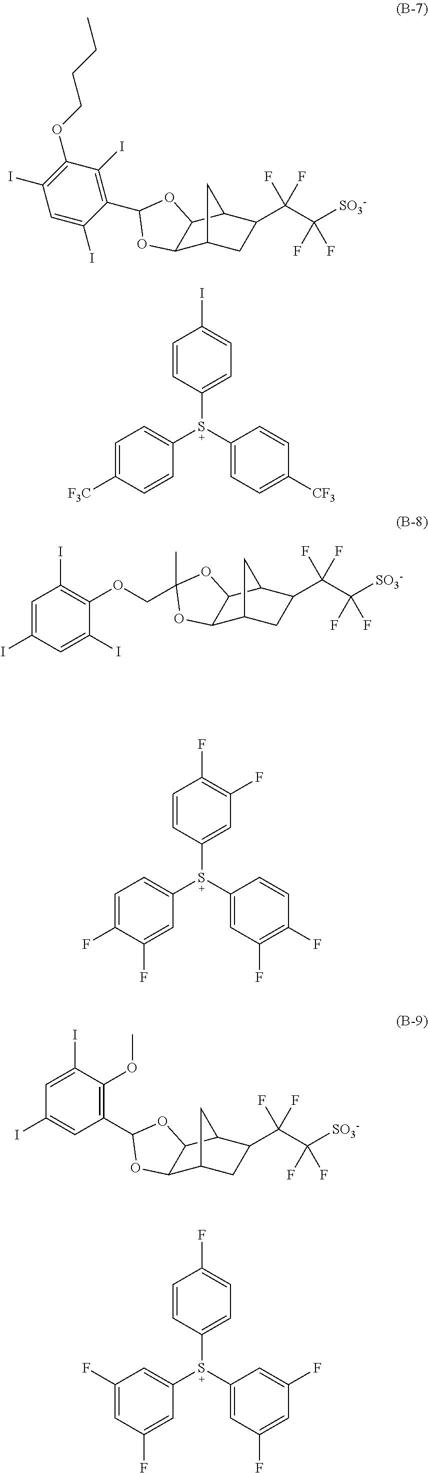

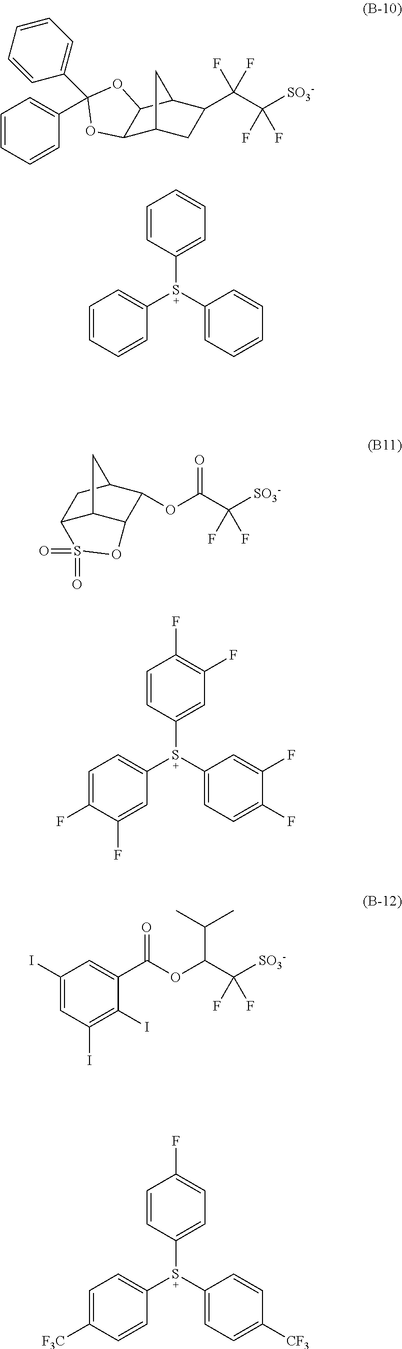

These radiation-sensitive onium salts (B) may be used singly, or two or more thereof may be used in combination. For example, the content of the radiation-sensitive onium salt (B) is 5 parts by mass or more and 45 parts by mass or less based on 100 parts by mass of the resin. The lower limit of the content of the radiation-sensitive acid generator is preferably 1 part by mass, more preferably 5 parts by mass, still more preferably 15 parts by mass, and particularly preferably 30 parts by mass based on 100 parts by mass of the resin. The upper limit of the content is preferably 60 parts by mass or less, more preferably 55 parts by mass or less, still more preferably 50 parts by mass or less, and particularly preferably 45 parts by mass or less based on 100 parts by mass of the resin. This makes it possible to exhibit superior sensitivity or CDU performance when forming a resist pattern.

In addition, the mass ratio of the content of the radiation-sensitive onium salt (A) to the content of the radiation-sensitive onium salt (B) in the composition is preferably 10:90 or more and 90:10 or less, more preferably 15:85 or more and 70:30 or less, and still more preferably 20:80 or more and 45:55 or more.

### <Acid Diffusion Controlling Agent>

The acid diffusion controlling agent contains an organic acid anion moiety and an onium cation moiety, and generates an acid having a higher pKa than that of an acid generated from the radiation-sensitive acid generator through irradiation with radiation. Examples of such an organic acid anion moiety includes carboxylic acids. The organic acid anion moiety preferably contains an iodine-substituted aromatic ring structure. The acid diffusion controlling agent is preferably represented by the following formula (S-1) or (S-2).

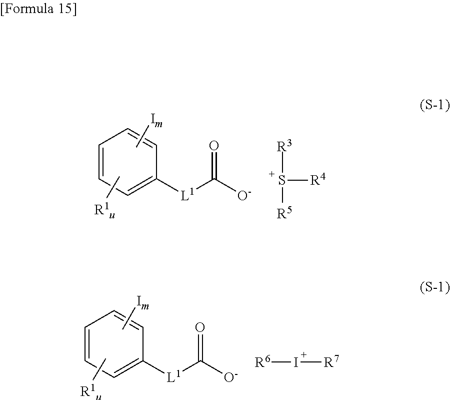

In the formulas (S-1) and (S-2), R¹ is a hydrogen atom, a hydroxy group, a fluorine atom, a chlorine atom, a bromine atom, an amino group, a nitro group, or a cyano group; or an alkyl group having 1 to 6 carbon atoms, an alkoxy group having 1 to 6 carbon atoms, an acyloxy group having 2 to 6 carbon atoms, or an alkylsulfonyloxy group having 1 to 4 carbon atoms, which may be substituted with a halogen atom; or —NR^{1A}—C(═O)—R^{1B} or —NR^{1A}—C(═O)—O—R^{1B}. R^{1A} is a hydrogen atom or an alkyl group having 1 to 6 carbon atoms, and R^{1B} is an alkyl group having 1 to 6 carbon atoms or an alkenyl group having 2 to 8 carbon atoms.

The alkyl group having 1 to 6 carbon atoms may be linear, branched, or cyclic, and specific examples thereof include a methyl group, an ethyl group, an n-propyl group, an isopropyl group, a cyclopropyl group, an n-butyl group, an isobutyl group, a sec-butyl group, a tert-butyl group, a cyclobutyl group, an n-pentyl group, a cyclopentyl group, an n-hexyl group, and a cyclohexyl group. Examples of the alkyl moiety of the alkoxy group having 1 to 6 carbon atoms, the acyloxy group having 2 to 7 carbon atoms, and the alkoxycarbonyl group having 2 to 7 carbon atoms include those the same as the specific examples of the alkyl group described above, and examples of the alkyl moiety of the alkylsulfonyloxy group having 1 to 4 carbon atoms include those having 1 to 4 carbon atoms among the specific examples of the alkyl group described above. The alkenyl group having 2 to 8 carbon atoms may be linear, branched, or cyclic, and specific examples thereof include a vinyl group, a 1-propenyl group, and a 2-propenyl group. Among them, a fluorine atom, a chlorine atom, a bromine atom, a hydroxy group, an amino group, an alkyl group having 1 to 3 carbon atoms, an alkoxy group having 1 to 3 carbon atoms, an acyloxy group having 2 to 4 carbon atoms, —NR^{1A}—C(═O)—R^{1B}, and —NR^{1A}—C(═O)—O—R^{1B} are preferable as R¹.

R³, R⁴, R⁵, R⁶, and R⁷ are each independently a monovalent hydrocarbon group having 1 to 20 carbon atoms optionally containing a heteroatom. When the onium cation moiety of the acid diffusion controlling agent has a fluorine atom, at least one among R³, R⁴, and R⁵ contains one or more fluorine atoms, and at least one of R⁶ and R⁷ contains one or more fluorine atoms. Any two among R³, R⁴, and R⁵ may be bonded to each other to form a ring together with a sulfur atom to which two thereof are bonded. The monovalent hydrocarbon group may be linear, branched, or cyclic, and specific examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonate ester linkage.

L¹ is a single bond or a divalent linking group having 1 to 20 carbon atoms, and may contain an ether linkage, a carbonyl group, an ester linkage, an amide linkage, a sultone ring, a lactam ring, a carbonate linkage, a halogen atom, a hydroxy group, or a carboxy group.

m and n are integers satisfying 0≤m≤5, 0≤n≤3, and 0≤m+n≤5, and preferably integers satisfying 1≤m≤3 and 0≤n≤2. When n is an integer satisfying 1≤r≤3, at least one R¹ is preferably a fluorine atom or a fluorinated hydrocarbon group.

Examples of the organic acid anion moiety of the acid diffusion controlling agent represented by the formula (S-1) or (S-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or another substituent.

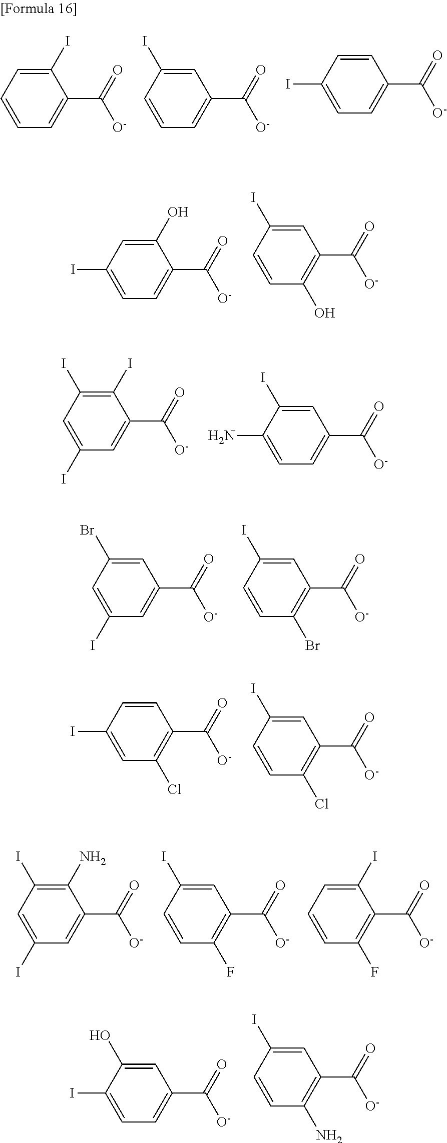

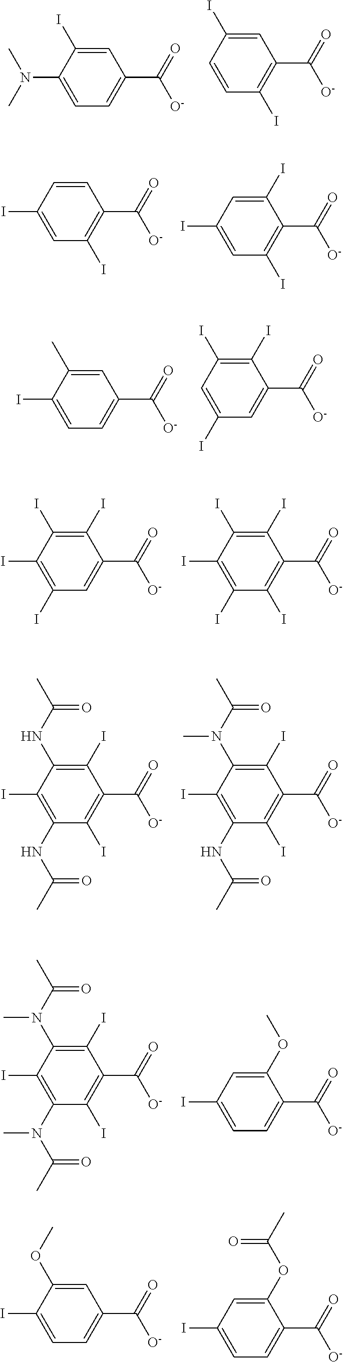

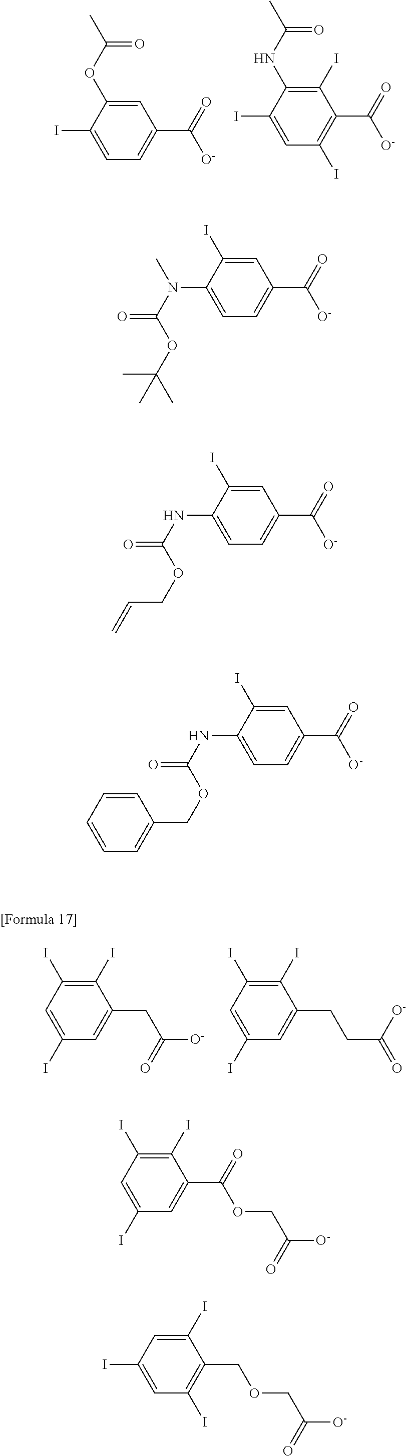

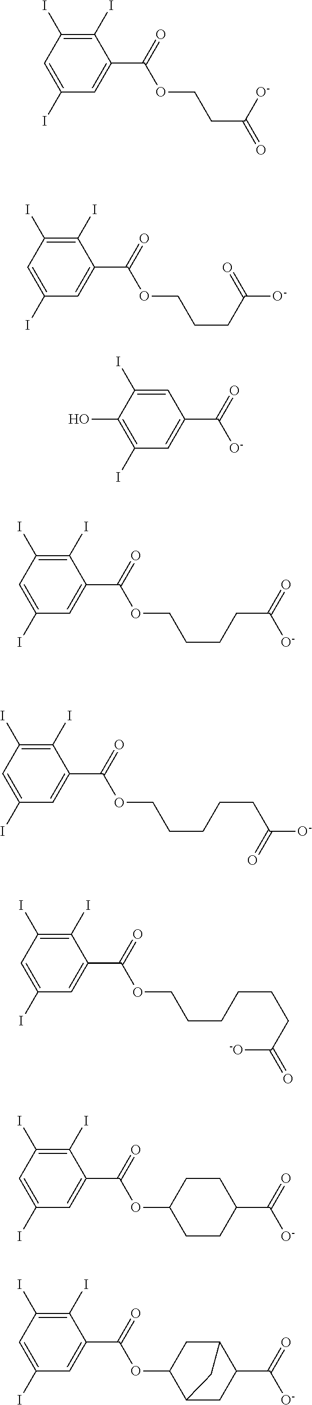

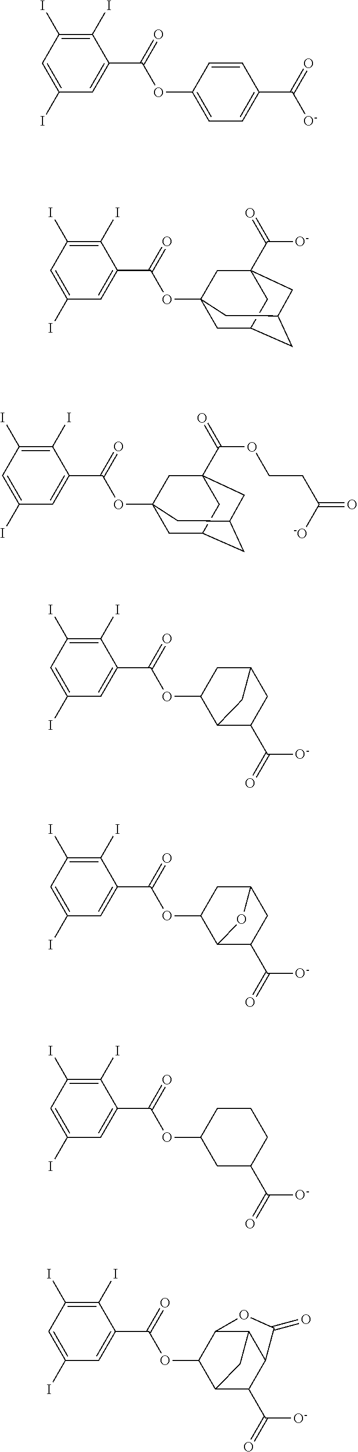

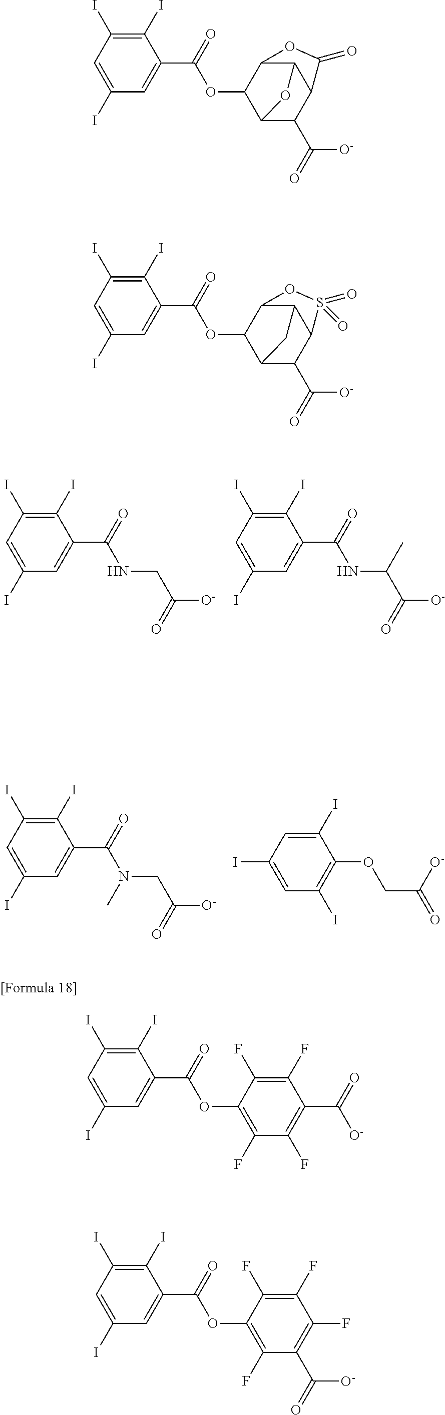

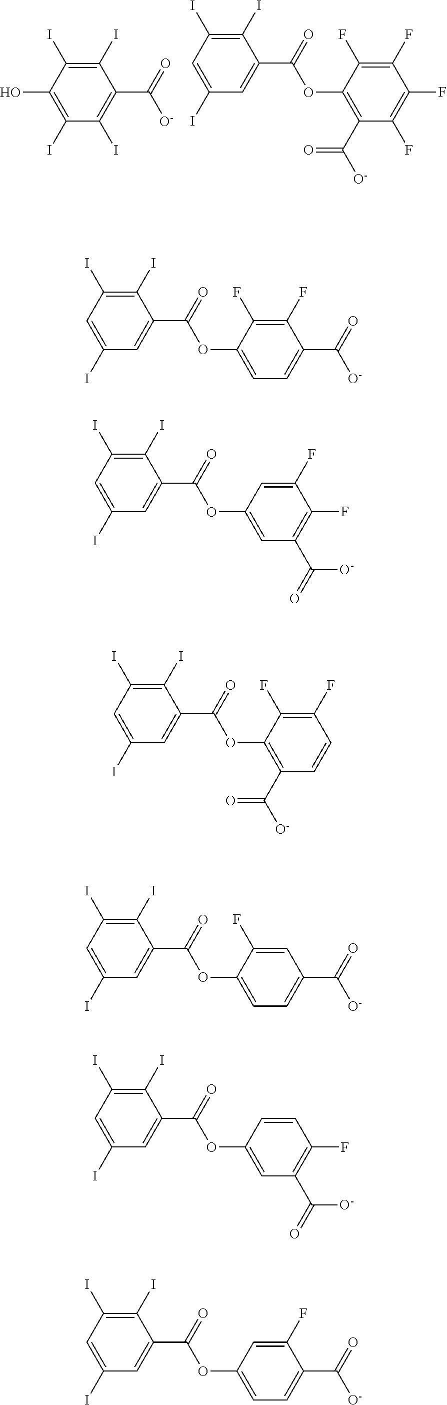

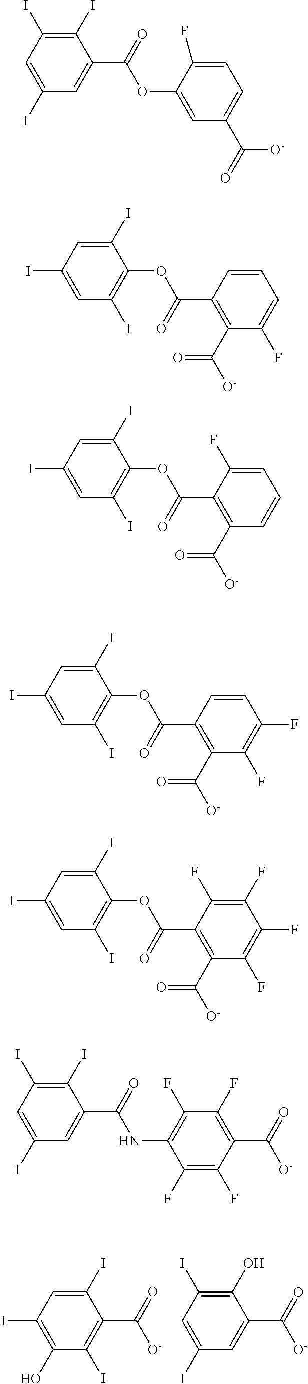

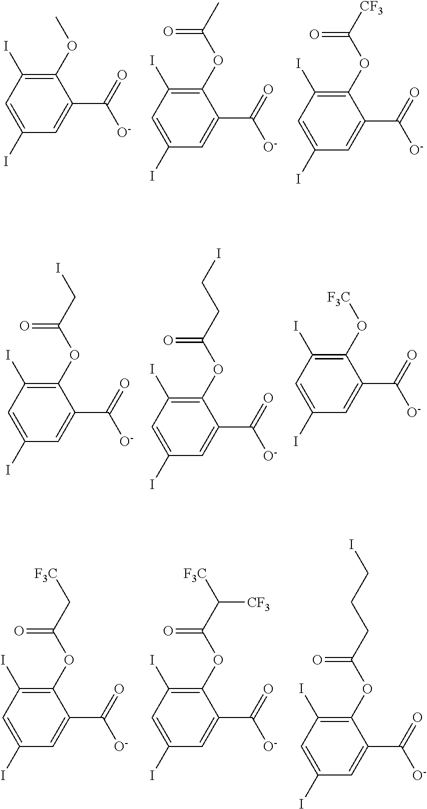

As the onium cation moieties in the acid diffusion controlling agents represented by the above formulas (S-1) and (S-2), onium cations containing an aromatic ring structure having a fluorine atom are preferable, and onium cations containing an aromatic ring structure having a fluorine atom or a CF₃ group are more preferable. Specific examples thereof include an onium cation represented by the above formula (3).

The acid diffusion controlling agents represented by the formulas (S-1) and (S-2) can be synthesized by a known method, particularly by a salt exchange reaction. A known acid diffusion controlling agent may be used as long as the effect of the present invention is not impaired.

These acid diffusion controlling agents may be used singly, or two or more thereof may be used in combination. The content ratio of the acid diffusion controlling agent is preferably 10% by mass or more, more preferably 15% by mass or more, and still more preferably 20% by mass or more based on the content of the radiation-sensitive acid generator. The ratio is preferably 100% by mass or less, more preferably 80% by mass or less, and still more preferably 60% by mass or less. This makes it possible to exhibit superior sensitivity or CDU performance when forming a resist pattern.

In addition, the content ratio of the acid diffusion controlling agent is preferably 10 mol % or more, more preferably 20 mol % or more, and still more preferably 30 mol % or more based on the radiation-sensitive acid generator (when a plurality of acid diffusion controlling agents is included, the total thereof). The ratio is preferably 50 mol % or less, more preferably 45 mol % or less, and still more preferably 40 mol % or less. This makes it possible to exhibit storage stability performance.

### <Resin>

The resin is an assembly of polymers containing a structural unit having an acid-dissociable group (hereinafter, also referred to as “structural unit (I)”) (this resin is hereinafter also referred to as “base resin”). The base resin may contain, in addition to the structural unit (I), a structural unit having a phenolic hydroxy group (II), a structural unit containing a heteroatom-containing substituent (III), a structural unit containing a lactone structure or the like (IV), or the like. Hereinafter, each of the structural units will be described.

### (Structural Unit (I))

The structural unit (I) is a structural unit having an acid-dissociable group. In the present description, the “acid-dissociable group” refers to a group that replaces a hydrogen atom of alkali-soluble groups such as a carboxy group, a phenolic hydroxy group, a sulfo group, and a sulfonamide group, and is dissociated by the action of an acid. Therefore, the acid-dissociable group is bonded to an oxygen atom that would otherwise be bonded to the hydrogen atom in these functional groups.

The structural unit (I) is not particularly limited as long as the structural unit (I) has an acid-dissociable group, and examples thereof include a structural unit having a tertiary alkyl ester moiety, a structural unit having a structure in which a hydrogen atom of a phenolic hydroxy group is replaced by a tertiary alkyl group, and a structural unit having an acetal linkage. Among them, a structural unit represented by the following formula (4) (hereinafter, also referred to as “structural unit (1-1)”) is preferable from the viewpoint of improvement in the pattern-forming performance of the radiation-sensitive resin composition.

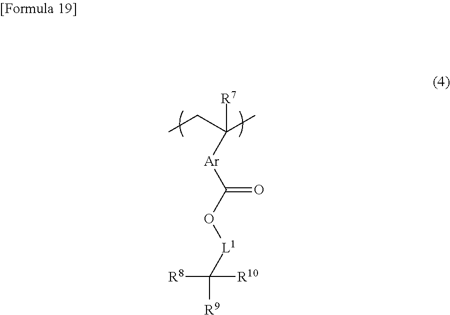

In the above formula (4), R⁷ is a hydrogen atom, a fluorine atom, a methyl group, or a trifluoromethyl group. R⁸ is a hydrogen atom or a monovalent hydrocarbon group having 1 to 20 carbon atoms. R⁹ and R¹⁰ are each independently a monovalent chain hydrocarbon group having 1 to 10 carbon atoms or a monovalent alicyclic hydrocarbon group having 3 to 20 carbon atoms, or represent a divalent alicyclic group having 3 to 20 carbon atoms composed of R⁹ and R¹⁰ combined with each other together with a carbon atom to which R⁹ and R¹⁰ are bonded. Ar is a single bond or a substituted or unsubstituted phenylene group. L¹ represents a single bond or a divalent linking group.

As R⁷, from the viewpoint of the copolymerizability of a monomer that affords the structural unit (1-1), a hydrogen atom and a methyl group are preferable, and a methyl group is more preferable.

Examples of the monovalent hydrocarbon group having 1 to 20 carbon atoms represented by R⁸ include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the chain hydrocarbon groups having 1 to 10 carbon atoms represented by R⁸ to R¹⁰ include a linear or branched saturated hydrocarbon group having 1 to 10 carbon atoms or a linear or branched unsaturated hydrocarbon group having 1 to 10 carbon atoms.

Examples of the alicyclic hydrocarbon groups having 3 to 20 carbon atoms represented by R⁸ to R¹⁰ include a monocyclic or polycyclic saturated hydrocarbon group or a monocyclic or polycyclic unsaturated hydrocarbon group. As the monocyclic saturated hydrocarbon group, a cyclopentyl group, a cyclohexyl group, a cycloheptyl group, and a cyclooctyl group are preferable. As the polycyclic group, bridged alicyclic hydrocarbon groups such as a norbornyl group, an adamantyl group, a tricyclodecyl group, and a tetracyclododecyl group are preferable. The bridged alicyclic hydrocarbon group refers to a polycyclic alicyclic hydrocarbon group in which two carbon atoms that constitute an alicyclic ring and are not adjacent to each other are bonded by a linking group containing one or more carbon atoms.

Examples of the monovalent aromatic hydrocarbon group having 6 to 20 carbon atoms represented by R⁸ include aryl groups such as a phenyl group, a tolyl group, a xylyl group, a naphthyl group, and an anthryl group; and aralkyl groups such as a benzyl group, a phenethyl group, and a naphthylmethyl group.

As R⁸, a linear or branched saturated hydrocarbon group having 1 to 10 carbon atoms, an alicyclic hydrocarbon group having 3 to 20 carbon atoms, and a monovalent aromatic hydrocarbon group having 6 to 10 carbon atoms are preferable.

The divalent alicyclic group having 3 to 20 carbon atoms composed of R⁹ and R¹⁰ combined with each other together with a carbon atom to which R⁹ and R¹⁰ are bonded is not particularly limited as long as the divalent alicyclic group is a group obtained by removing two hydrogen atoms from an identical carbon atom constituting a carbon ring of a monocyclic or polycyclic alicyclic hydrocarbon having the aforementioned number of carbon atoms. The divalent alicyclic group may be either a monocyclic hydrocarbon group or a polycyclic hydrocarbon group, and the polycyclic hydrocarbon group may be either a bridged alicyclic hydrocarbon group or a fused alicyclic hydrocarbon group, and may be either a saturated hydrocarbon group or an unsaturated hydrocarbon group. The fused alicyclic hydrocarbon group refers to a polycyclic alicyclic hydrocarbon group composed of a plurality of alicyclic rings sharing a side (a bond between two adjacent carbon atoms).

Among the monocyclic alicyclic hydrocarbon groups, the saturated hydrocarbon group is preferably a cyclopentanediyl group, a cyclohexanediyl group, a cycloheptanediyl group, a cyclooctanediyl group, or the like, and the unsaturated hydrocarbon group is preferably a cyclopentenediyl group, a cyclohexenediyl group, a cycloheptenediyl group, a cyclooctenediyl group, a cyclodecenediyl group, or the like. As the polycyclic alicyclic hydrocarbon group, bridged alicyclic saturated hydrocarbon groups are preferable, and for example, a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group) are preferable.

The phenylene group represented by Ar may be any of a 1,4-phenylene group, a 1,3-phenylene group, and a 1,2-phenylene group.

Examples of the divalent linking group represented by L¹ include an alkanediyl group, a cycloalkanediyl group, an alkenediyl group, *—R^{LA}O—, and *—R^{LB}COO— (* represents a bond with an oxygen atom). It is noted that in the case of a group other than *—R^{LB}COO—, the carbon atom bonded to the oxygen atom of —COO— in the formula (4) is a tertiary carbon and has no hydrogen atom.

Some or all of the hydrogen atoms on the carbon atom in R⁸ to R¹⁰ and L¹ may be replaced by a halogen atom such as a fluorine atom, a chlorine atom, or an iodine atom, a halogenated alkyl group such as a trifluoromethyl group, an alkoxy group such as a methoxy group, a cyano group, or the like.

Examples of the alkanediyl group include a methanediyl group, a 1,1-ethanediyl group, a 1,2-ethanediyl group, a 1,1-propanediyl group, a 1,2-propanediyl group, a 1,3-propanediyl group, a 1,4-butanediyl group, a 1,5-pentanediyl group, a 1,6-hexanediyl group, a 1,7-heptanediyl group, a 1,8-octanediyl group, a 1,9-nonanediyl group, and a 1,10-decanediyl group. The alkanediyl group is preferably an alkanediyl group having 1 to 8 carbon atoms.

Examples of the cycloalkanediyl group include monocyclic cycloalkanediyl groups such as a cyclopentanediyl group and a cyclohexanediyl group; and polycyclic cycloalkanediyl groups such as a norbornanediyl group and an adamantanediyl group. The cycloalkanediyl group is preferably a cycloalkanediyl group having 5 to 12 carbon atoms.

Examples of the alkenediyl group include an ethenediyl group, a propanediyl group, and a butenediyl group. The alkenediyl group is preferably an alkenediyl group having 2 to 6 carbon atoms.

Examples of R^{LA} of *—R^{LA}O— include the alkanediyl group, the cycloalkanediyl group, and the alkenediyl group. Examples of R^{LB} of *—R^{LB}COO— include the alkanediyl group, the cycloalkanediyl group, the alkenediyl group, and an arenediyl group. Examples of the arenediyl group include a phenylene group, a tolylene group, and a naphthylene group. The arenediyl group is preferably an arenediyl group having 6 to 15 carbon atoms.

Among them, it is preferable that R⁸ be an alkyl group having 1 to 4 carbon atoms or an aryl group having 6 to 10 carbon atoms, and the alicyclic structure composed of R⁹ and R¹⁰ combined with each other together with a carbon atom to which R⁹ and R¹⁰ are bonded be a polycyclic or monocyclic cycloalkane structure. L¹ is preferably a single bond or *—R^{LA}O—. R^{LA} is preferably an alkanediyl group.

Examples of the structural unit (1-1) include structural units represented by the following formulas (3-1) to (3-8) (hereinafter, also referred to as “structural units (1-1-1) to (1-1-8)”).

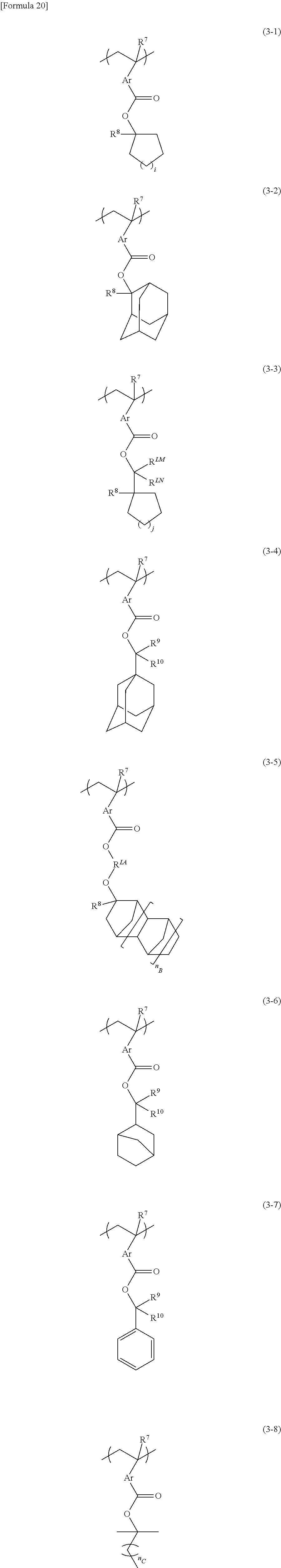

In the formulas (3-1) to (3-8), R⁷ to R¹⁰, R^{LA}, and Ar have the same meaning as in the formula (4). R^{LM} and R^{LN} are each independently a monovalent hydrocarbon group having 1 to 10 carbon atoms. i and j are each independently an integer of 1 to 4. n_{A}, n_{B}, and n_{C} are each independently 0 or 1.

Examples of R^{LM} and R^{LN} include groups corresponding to the monovalent hydrocarbon groups having 1 to 10 carbon atoms among the monovalent hydrocarbon groups having 1 to 20 carbon atoms represented by R⁸ of the formula (4). As R^{LM} and R^{LN}, a methyl group, an ethyl group, or an isopropyl group is preferable.

i and j are preferably 1, 2, or 4. As R⁸ to R¹⁰, a methyl group, an ethyl group, an isopropyl group, a phenyl group, or an iodophenyl group is preferable.

The base resin may contain one type of the structural unit (I) or two or more types of the structural unit (I) in combination.

Furthermore, the resin may contain, as the structural unit (I), a structural unit represented by the following formulas (1f) to (2f) together with or in place of the structural unit (1-1).

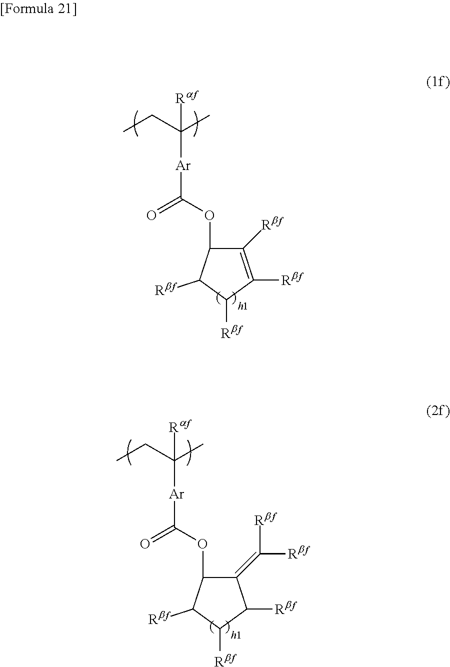

In the formulas (1f) to (2f), R^{αf} is independently at each occurrence a hydrogen atom, a fluorine atom, a methyl group, or a trifluoromethyl group. R^{βf} is independently at each occurrence a hydrogen atom or a chain alkyl group having 1 to 5 carbon atoms. Ar has the same meaning as in the formula (4). h₁ is independently at each occurrence an integer of 1 to 4.

As the R^{βf}, a hydrogen atom, a methyl group, or an ethyl group is preferable. h₁ is preferably 1 or 2.

The lower limit of the content ratio of the structural unit (I) is preferably 20 mol %, more preferably 30 mol %, still more preferably 40 mol %, and particularly preferably 50 mol % based on all the structural units composing the base resin. The upper limit of the content ratio is preferably 90 mol %, more preferably 80 mol %, still more preferably 70 mol %, and particularly preferably 65 mol %. When the content ratio of the structural unit (I) is set to fall within the above range, the pattern-forming performance of the radiation-sensitive resin composition can further be improved.

### (Structural Unit (II))

The structural unit (II) is a structural unit having a phenolic hydroxy group, provided that a case where the structural unit corresponds to the structural unit (I) is excluded. In the present invention, a phenolic hydroxy group generated through deprotection due to the action of an acid generated by exposure to light is also included as the phenolic hydroxy group of the structural unit (II). Owing to the fact that the resin contains the structural unit (II), the solubility in a developer can be more appropriately adjusted, and as a result, the sensitivity and the like of the radiation-sensitive resin composition can be further improved. When KrF excimer laser light, EUV, electron beam or the like is used as radiation to be applied in an exposure step in a resist pattern formation method, the structural unit (II) contributes to improvement in etching resistance and improvement in difference in solubility in a developer between an exposed area and an unexposed area (dissolution contrast). In particular, the polymer containing the structural unit (III) can be suitably applied for pattern formation using exposure with radiation having a wavelength of 50 nm or less, such as an electron beam or EUV. The structural unit (II) is preferably represented by the following formula (5).

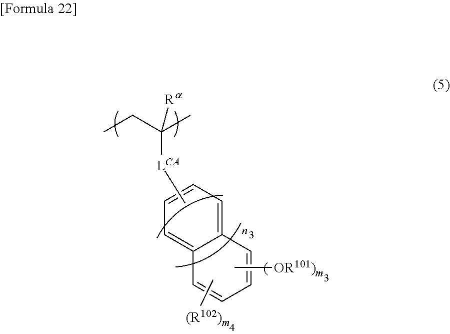

In the formula (5),
R^{α} is a hydrogen atom, a fluorine atom, a methyl group, or a trifluoromethyl group;
L^{CA} is a single bond, —COO—*, or —O—; * is a bond on the aromatic ring side;
R¹⁰¹ is a hydrogen atom or a protective group that is deprotected by the action of an acid; when there are a plurality of R¹⁰¹s, the plurality of R¹⁰¹s are the same as or different from each other;
R¹⁰² is a cyano group, a nitro group, an alkyl group, a fluorinated alkyl group, an alkoxycarbonyloxy group, an acyl group, or an acyloxy group; when there are a plurality of R¹⁰²'s, the plurality of R¹⁰²'s are the same or different from each other;
n₃ is an integer of 0 to 2, m₃ is an integer of 1 to 8, and m₄ is an integer of 0 to 8, provided that 1≤m₃+m₄≤2n₃+5 is satisfied.

The R^{α} is preferably a hydrogen atom or a methyl group from the viewpoint of the copolymerizability of a monomer that affords the structural unit (II).

L^{CA} is preferably a single bond or —COO—*.

Examples of the protective group that is deprotected due to the action of the acid represented by R¹⁰¹ include groups represented by the following formulas (AL-1) to (AL-3).

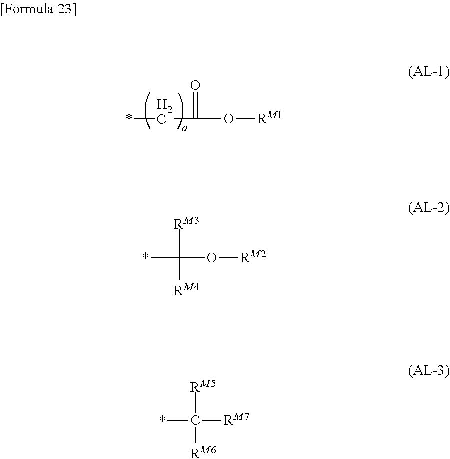

In the formulas (AL-1) and (AL-2), R^{M1} and R^{M2} are monovalent hydrocarbon groups, and may contain a heteroatom such as an oxygen atom, a sulfur atom, a nitrogen atom, or a fluorine atom. The monovalent hydrocarbon group may be linear, branched, or cyclic, and is preferably an alkyl group having 1 to 40 carbon atoms, and more preferably an alkyl group having 1 to 20 carbon atoms. In the formula (AL-1), a is an integer of 0 to 10, and is preferably an integer of 1 to 5. In the formulas (AL-1) to (AL-3), * is a bond to another moiety.

In the formula (AL-2), R^{M3} and R^{M4} are each independently a hydrogen atom or a monovalent hydrocarbon group, and may contain a heteroatom such as an oxygen atom, a sulfur atom, a nitrogen atom, or a fluorine atom. The monovalent hydrocarbon group may be linear, branched, or cyclic, and preferably an alkyl group having 1 to 20 carbon atoms. Any two among R^{M2}, R^{M3}, and R^{M4} may be bonded to each other to form a ring having 3 to 20 carbon atoms together with a carbon atom or a carbon atom and an oxygen atom to which two thereof are bonded. The ring is preferably a ring having 4 to 16 carbon atoms, and particularly preferably an alicyclic ring.

In the formula (AL-3), R^{M5}, R^{M6}, and R^{M7} are each independently a monovalent hydrocarbon group, and may contain a heteroatom such as an oxygen atom, a sulfur atom, a nitrogen atom, or a fluorine atom. The monovalent hydrocarbon group may be linear, branched, or cyclic, and preferably an alkyl group having 1 to 20 carbon atoms. Any two among R^{M5}, R^{M6}, and R^{M7} may be bonded to each other to form a ring having 3 to 20 carbon atoms together with the carbon atom to which they are bonded. The ring is preferably a ring having 4 to 16 carbon atoms, and particularly preferably an alicyclic ring.

Among them, the protective group that is deprotected by the action of an acid is preferably a group represented by the formula (AL-3).

Examples of the alkyl group as R¹⁰² include linear or branched alkyl groups having 1 to 8 carbon atoms such as a methyl group, an ethyl group, and a propyl group. Examples of the fluorinated alkyl group include linear or branched fluorinated alkyl groups having 1 to 8 carbon atoms such as a trifluoromethyl group and a pentafluoroethyl group. Examples of the alkoxycarbonyloxy group include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms such as an acetyl group, a propionyl group, a benzoyl group, and an acryloyl group. Examples of the acyloxy group include aliphatic or aromatic acyloxy groups having 2 to 12 carbon atoms such as an acetyloxy group, a propionyloxy group, a benzoyloxy group, and an acryloyloxy group.

The n₃ is more preferably 0 or 1, and still more preferably 0.

m₃ is preferably an integer of 1 to 3, and more preferably 1 or 2.

m₄ is preferably an integer of 0 to 3, and more preferably an integer of 0 to 2.

As the structural unit (II), structural units represented by the following formulas (2-1) to (2-11) (hereinafter, also referred to as “structural units (2-1) to (2-11)”) and the like are preferable.

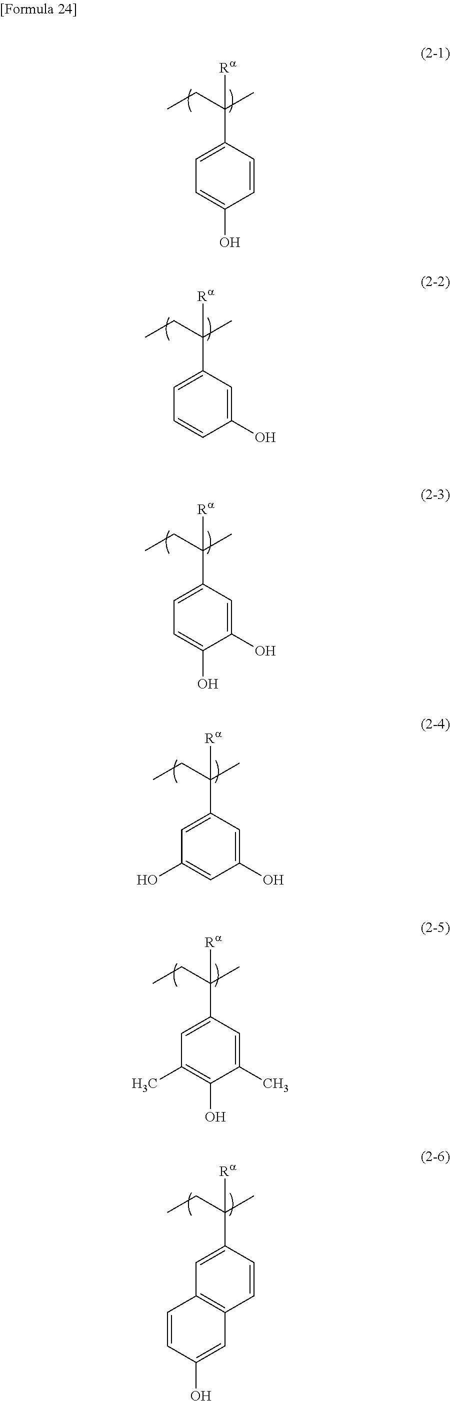

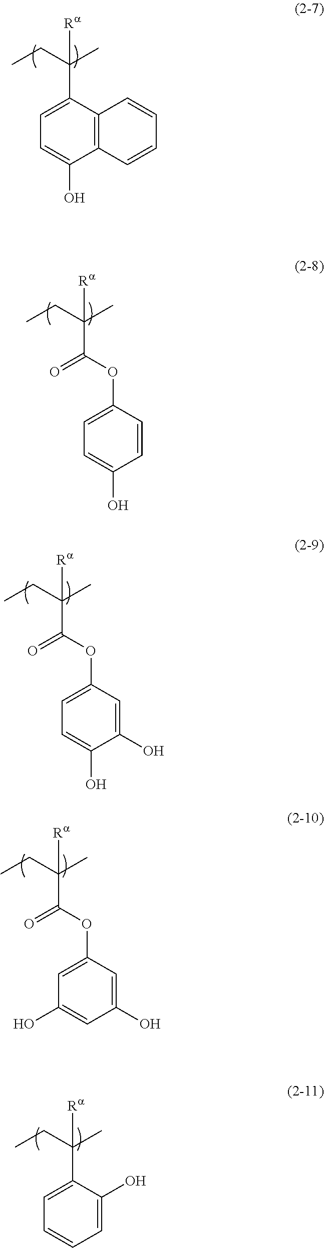

In the formulas (2-1) to (2-11), R^{α} is the same as in the formula (2).

Among them, the structural units (2-1) to (2-4), (2-6), (2-8), (2-9), and (2-11) are preferable.

The lower limit of the content ratio of the structural unit (II) (when there is a plurality of types of the structural unit (II), the total thereof) is preferably 10 mol %, more preferably 15 mol %, still more preferably 20 mol %, and particularly preferably 25 mol % based on all the structural units composing the resin. The upper limit of the content ratio is preferably 60 mol %, more preferably 55 mol %, still more preferably 50 mol %, and particularly preferably 45 mol %. When the content ratio of the structural unit (II) is set to fall within the above range, the sensitivity, CDU performance, and resolution of the radiation-sensitive resin composition can be further improved.

In the case of polymerizing a monomer having a phenolic hydroxy group such as hydroxystyrene, it is preferable to polymerize the monomer with the phenolic hydroxy group protected by a protective group such as an alkali-dissociable group, and then perform deprotection by hydrolysis to obtain a structural unit (II).

### (Structural Unit (III))

The structural unit (III) is a structural unit having a heteroatom-containing substituent such as a fluorine atom, an alcoholic hydroxy group, a carboxy group, a cyano group, a nitro group, or a sulfonamide group (excluding structures corresponding to the structural units (I) to (II)). Among them, a structural unit having a fluorine atom, a structural unit having an alcoholic hydroxy group, and a structural unit having a carboxy group are preferable, and a structural unit having a fluorine atom and a structural unit having an alcoholic hydroxy group are more preferable.

Examples of the structural unit (III) include structural units represented by the following formulas.

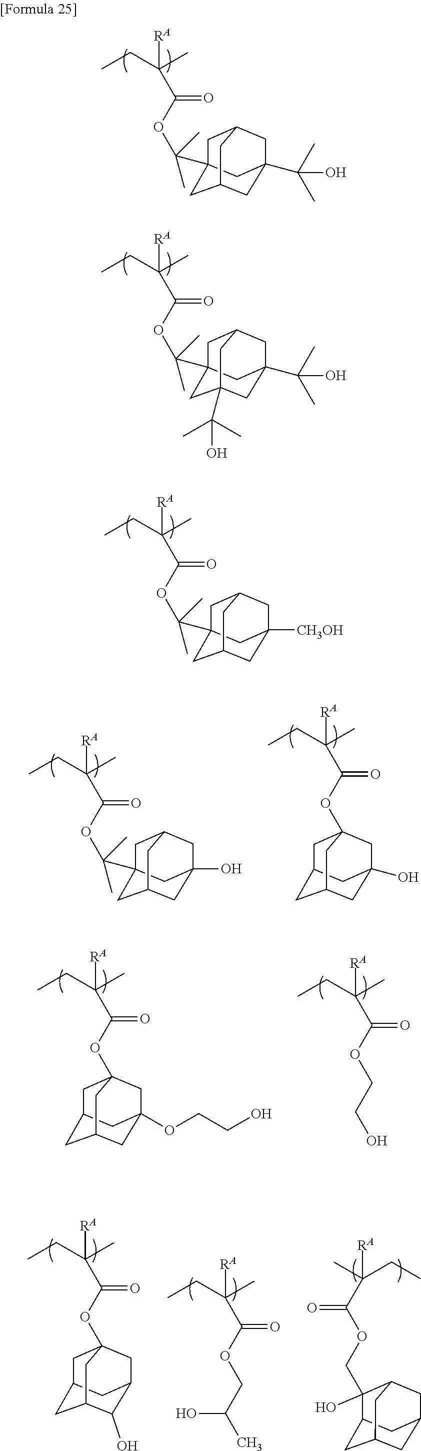

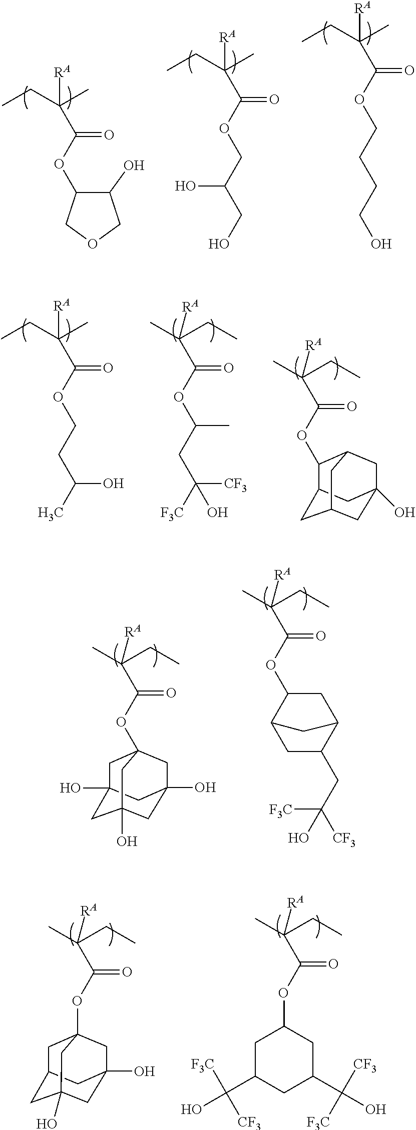

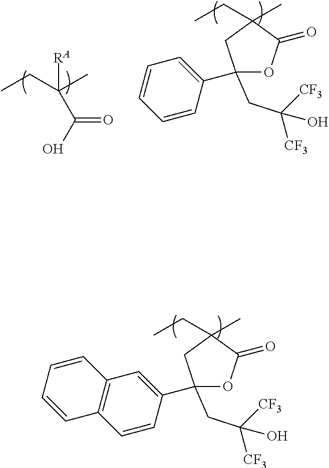

In the formulas, R^{A} is a hydrogen atom, a fluorine atom, a methyl group, or a trifluoromethyl group.

When the resin contains the structural unit (III), the lower limit of the content ratio of the structural unit (III) is preferably 3 mol %, more preferably 5 mol %, and still more preferably 8 mol % based on all the structural units composing the resin. The upper limit of the content ratio is preferably 20 mol %, more preferably 15 mol %, and still more preferably 12 mol %. When the content ratio of the structural unit (III) is set to fall within the above range, the solubility of the resin in a developer can be made more appropriate.

### (Structural Unit (IV))

The structural unit (IV) is a structural unit containing at least one selected from the group consisting of a lactone structure, a cyclic carbonate structure, and a sultone structure. When the base resin further has the structural unit (IV), the solubility in a developer can be adjusted, and as a result, the lithographic performance such as resolution of the radiation-sensitive resin composition can be improved. In addition, the adhesion between a resist pattern formed from the base resin and a substrate can be improved.

### (Method for Synthesizing Resin)

The resin as a base resin can be synthesized by, for example, subjecting monomers that afford structural units to a polymerization reaction in an appropriate solvent using a publicly known radical polymerization initiator or the like.

The molecular weight of the resin as a base resin is not particularly limited, and the lower limit of the weight-average molecular weight (Mw) as determined by Gel Permeation Chromatography (GPC) relative to standard polystyrene is preferably 1,000, more preferably 2,000, still more preferably 3,000, and particularly preferably 4,000. The upper limit of the Mw is preferably 30,000, more preferably 20,000, still more preferably 10,000, and particularly preferably 8,000. When the Mw of the resin is within the above range, a resulting resist film is good in heat resistance and developability.

The ratio (Mw/Mn) of Mw to the number-average molecular weight (Mn) of the resin as a base resin as determined by GPC relative to standard polystyrene is usually 1 or more and 5 or less, preferably 1 or more and 3 or less, and more preferably 1 or more and 2 or less.

The method for measuring Mw and Mn of a resin in the present description is as described in Examples.

The content of the resin is preferably 70% by mass or more, more preferably 75% by mass or more, and still more preferably 80% by mass or more based on the total solid content of the radiation-sensitive resin composition.

### (Structural Unit (V))

The resin may contain a structural unit having an organic acid anion moiety and an onium cation moiety as an additional structural unit (V). Owing to the fact that the resin contains the structural unit (V), the resin can function as an acid generator. In this case, the composition may or may not contain a radiation-sensitive acid generator. The structural unit (V) is preferably represented by the following formula (a1) or (a2).

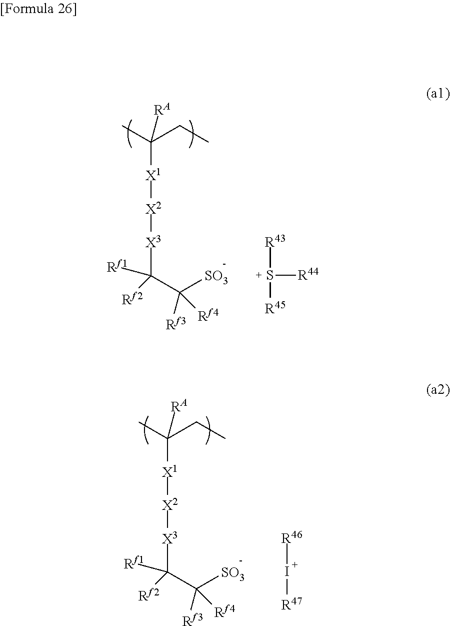

In the formulas, R^{A} is a hydrogen atom or a methyl group. X¹ is a single bond or an ester group. X² is a linear, branched or cyclic alkylene group having 1 to 12 carbon atoms or an arylene group having 6 to 10 carbon atoms, and some of the methylene groups constituting the alkylene group may be replaced by an ether group, an ester group, or a lactone ring-containing group. At least one hydrogen atom contained in X² may be replaced by an iodine atom. X³ is a single bond, an ether group, an ester group, or a linear, branched or cyclic alkylene group having 1 to 12 carbon atoms, and some of the methylene groups constituting the alkylene group may be replaced by an ether group or an ester group. Rf¹ to Rf⁴ are each independently a hydrogen atom, a fluorine atom, or a trifluoromethyl group, and at least one among Rf¹ to Rf⁴ is a fluorine atom or a fluorinated hydrocarbon group. R⁴³ to R⁴⁷ are each independently a monovalent hydrocarbon group having 1 to 20 carbon atoms and optionally containing a heteroatom, and R⁴³ and R⁴⁴ may be bonded to each other to form a ring together with a sulfur atom to which R⁴³ and R⁴⁴ are bonded.

As the monovalent hydrocarbon group having 1 to 20 carbon atoms and optionally containing a heteroatom in R⁴³ to R⁴⁷, an alkyl group having 1 to 12 carbon atoms, a cycloalkyl group having 3 to 12 carbon atoms, or an aryl group having 6 to 20 carbon atoms is preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups composing these groups may be replaced by an ether group, an ester group, a carbonyl group, a carbonate group, or a sulfonate ester group.

The formulas (a1) and (a2) are preferably represented by the following formulas (a1-1) and (a2-1), respectively.

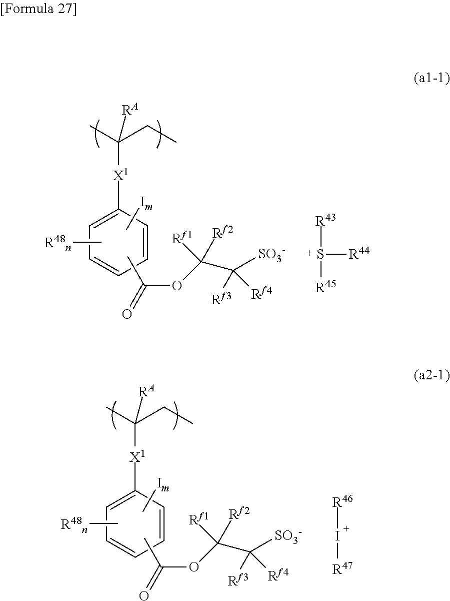

In the formulas, R^{A}, R⁴³ to R⁴⁷, Rf¹ to Rf⁴, and X¹ have the same meaning as in the formula (a1) or (a2). R⁴⁸ is a linear, branched or cyclic alkyl group having 1 to 4 carbon atoms, a halogen atom other than an iodine atom, a hydroxy group, a linear, branched or cyclic alkoxy group having 1 to 4 carbon atoms, or a linear, branched or cyclic alkoxycarbonyl group having 2 to 5 carbon atoms. m is an integer of 0 to 4. n is an integer of 0 to 3.

Examples of the organic acid anion moiety of the monomer that affords the structural unit (V) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or another substituent.

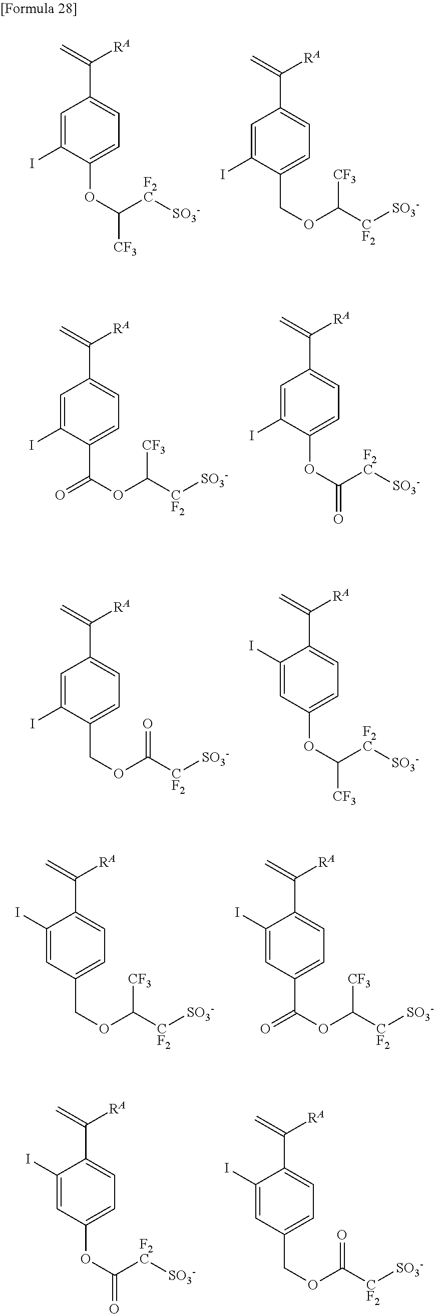

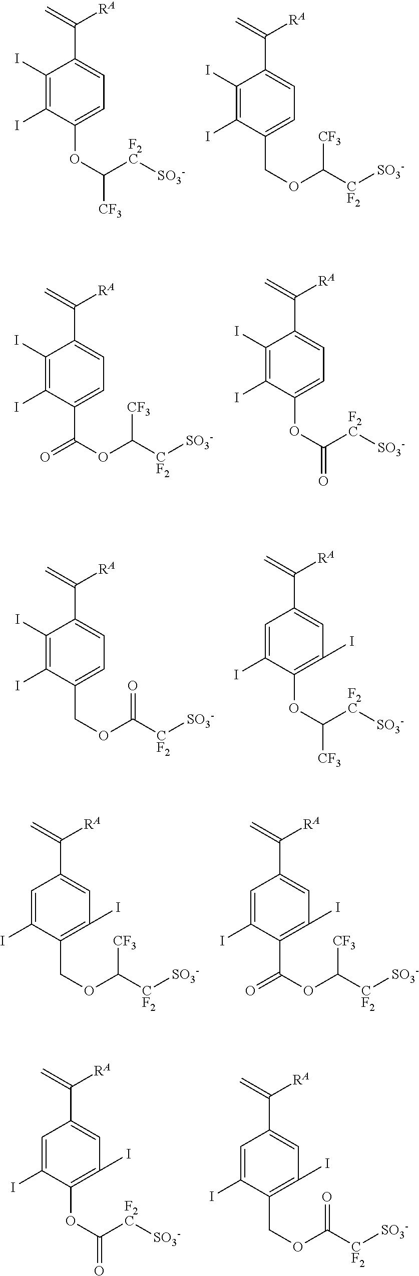

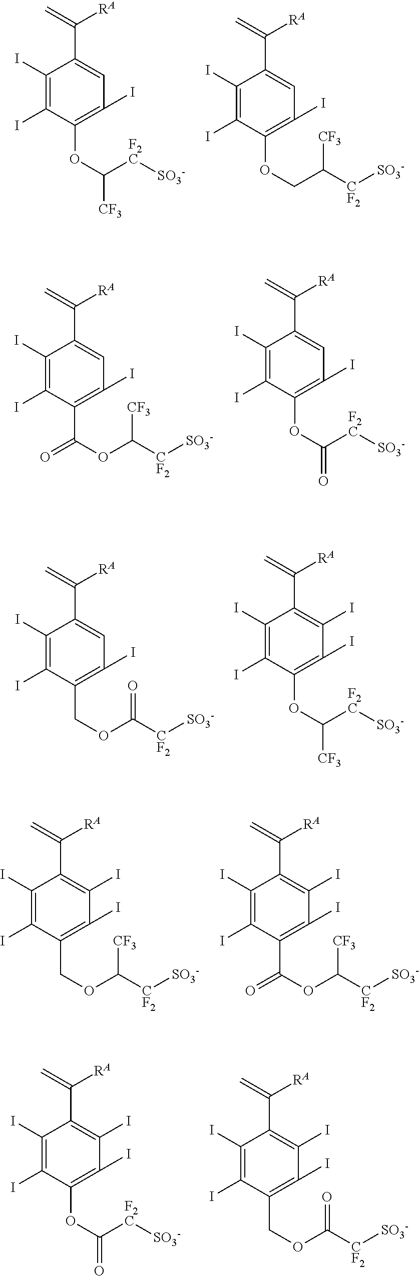

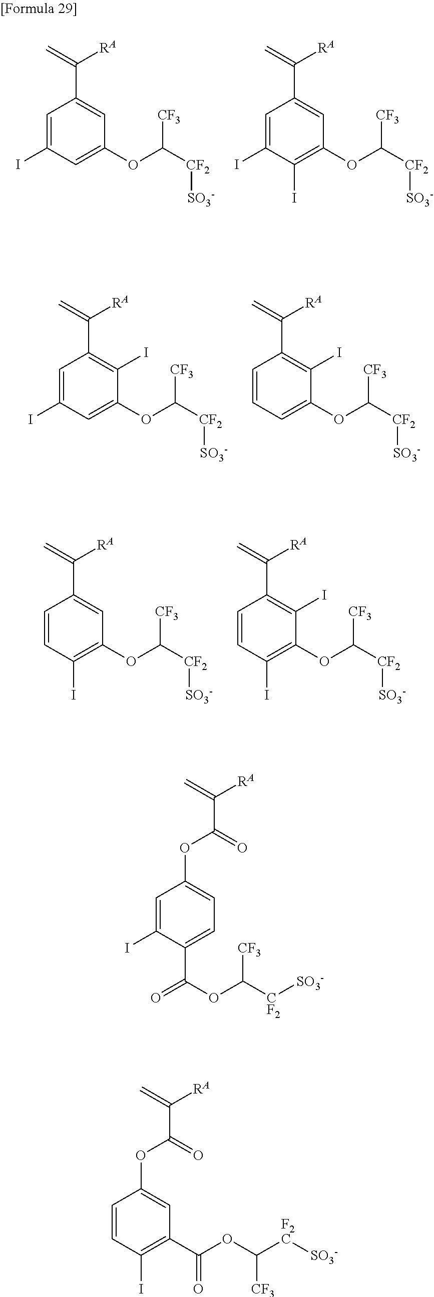

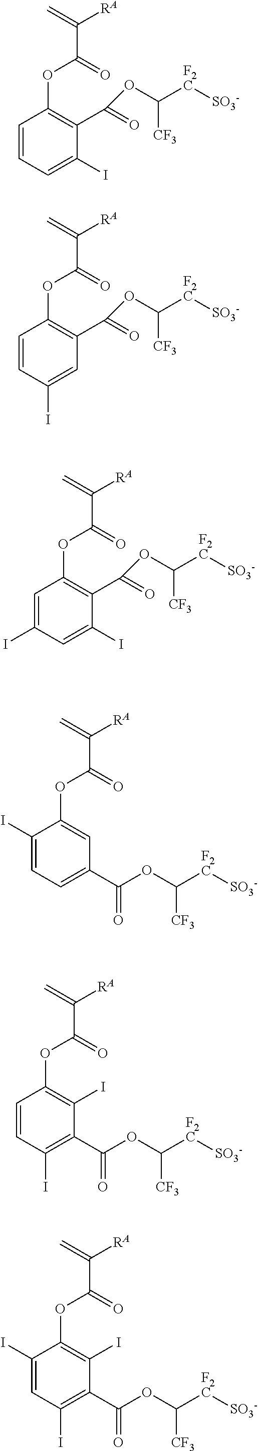

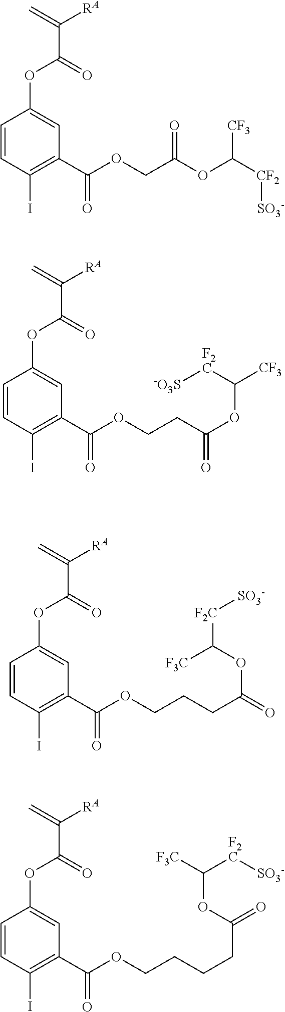

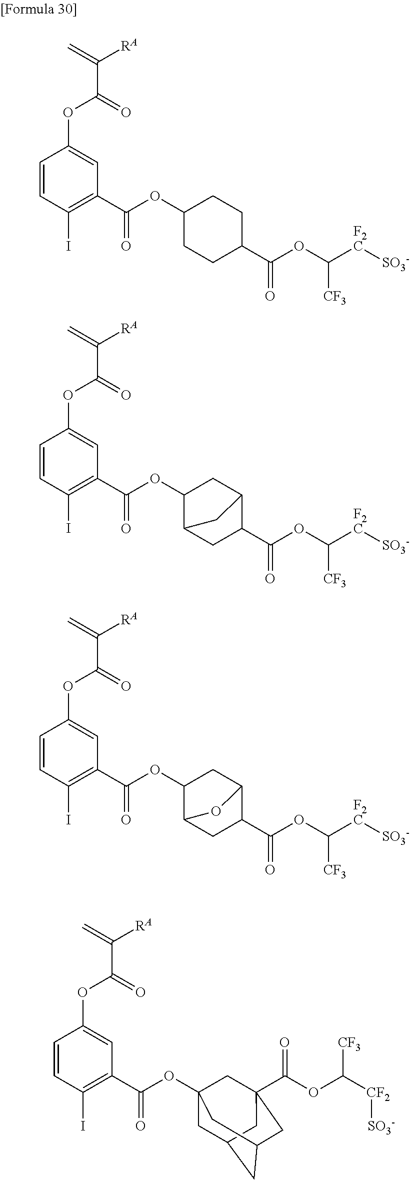

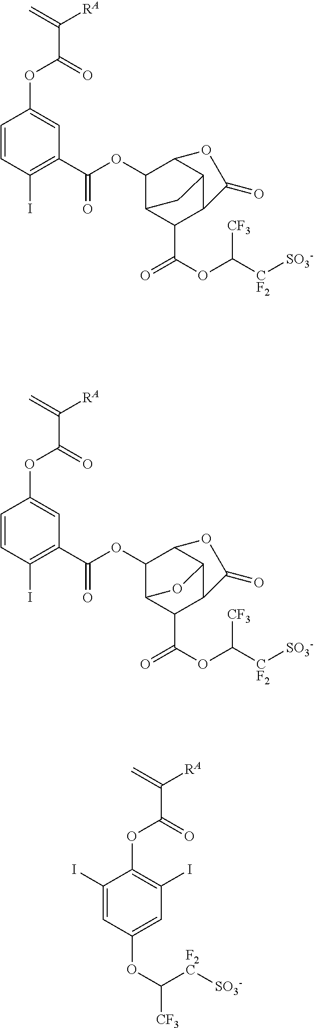

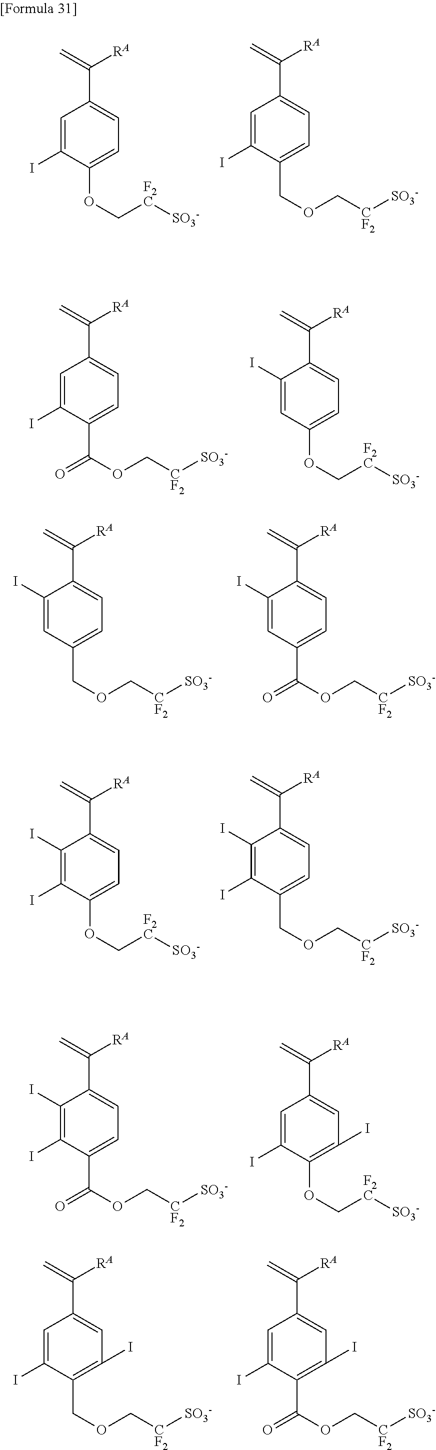

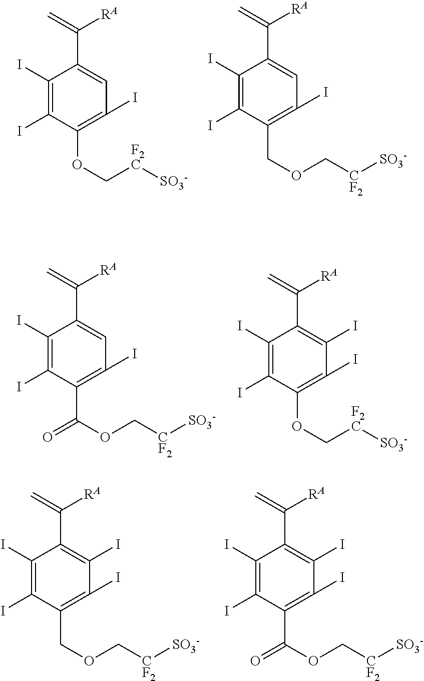

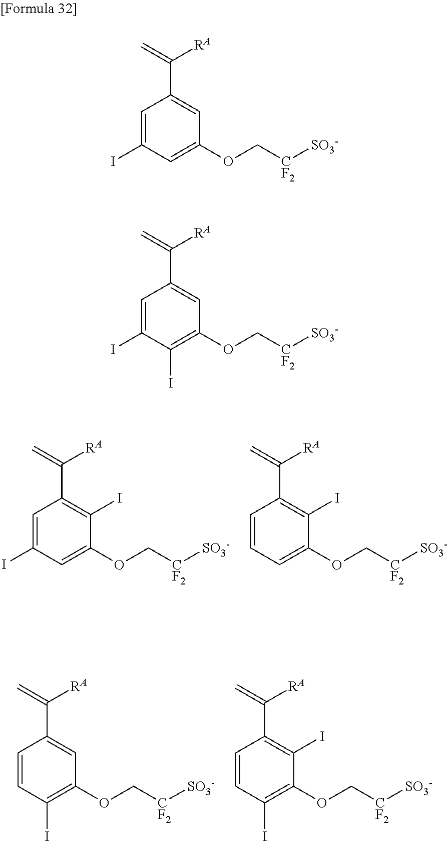

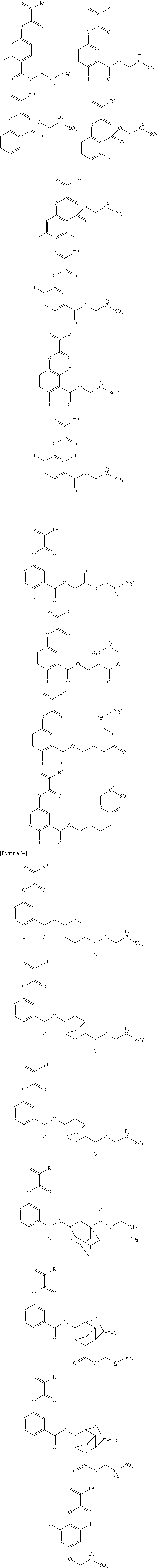

As the onium cation moiety in the structural unit (V), an onium cation moieties of the radiation-sensitive acid generator and the acid diffusion controlling agent can be suitably employed.

When the resin contains the structural unit (V), the lower limit of the content ratio of the structural unit (V) (when a plurality of types of the structural unit (V) is contained, the total content ratio of them) is preferably 5 mol %, more preferably 10 mol %, still more preferably 12 mol % based on all the structural units constituting the base resin. The upper limit of the content ratio is preferably 30 mol %, more preferably 25 mol %, and still more preferably 20 mol %. When the content ratio of the structural unit (V) is set to fall within the above range, a function of the resin as an acid generator can be sufficiently exhibited.

The monomer that affords the structural unit (V) can be synthesized, for example, by the same method as that for a sulfonium salt having a polymerizable anion described in JP-B-5201363.

### <Other Resins>

The radiation-sensitive resin composition according to the present embodiment may include, as another resin, a resin having higher content by mass of fluorine atoms than the above-described base resin (hereinafter, also referred to as a “high fluorine-content resin”). When the radiation-sensitive resin composition includes the high fluorine-content resin, the high fluorine-containing resin can be localized in the surface layer of a resist film compared to the base resin, and as a result, the state of the surface of the resist film and the component distribution in the resist film can be controlled to a desired state.

### (Method for Synthesizing High Fluorine-Content Resin)

The high fluorine-content resin can be synthesized by the same method as the method for synthesizing the base resin described above.

### <Solvent>

The radiation-sensitive resin composition according to the present embodiment includes a solvent. The solvent is not particularly limited as long as the solvent is a solvent capable of dissolving or dispersing at least the onium salt, the base resin, and additives or the like contained as desired.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
monoalcohol-based solvents having 1 to 18 carbon atoms, such as iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
polyhydric alcohol-based solvents having 2 to 18 carbon atoms, such as ethylene glycol, 1,2-propylene glycol, 2-methyl-2,4-pentanediol, 2,5-hexanediol, diethylene glycol, dipropylene glycol, triethylene glycol, and tripropylene glycol; and
partially etherized polyhydric alcohol-based solvents resulting from etherification of some of the hydroxy groups of the above-described polyhydric alcohol-based solvents.

In the present embodiment, alcohol acid ester-based solvents such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate are also included in the alcohol-based solvent.

Examples of the ether-based solvent include:
dialkyl ether-based solvents, such as diethyl ether, dipropyl ether, and dibutyl ether;
cyclic ether-based solvents, such as tetrahydrofuran and tetrahydropyran;
aromatic ring-containing ether-based solvents, such as diphenyl ether and anisole (methyl phenyl ether); and
polyhydric alcohol ether-based solvents resulting from etherification of hydroxy groups of the above-described polyhydric alcohol-based solvent.

Examples of the ketone-based solvent include chain ketone-based solvents, such as acetone, butanone, and methyl-iso-butyl ketone;
cyclic ketone-based solvents, such as cyclopentanone, cyclohexanone, and methylcyclohexanone; and
2,4-pentanedione, acetonylacetone, and acetophenone.

Examples of the amide-based solvent include cyclic amide-based solvents, such as N,N′-dimethylimidazolidinone and N-methylpyrrolidone; and
chain amide-based solvents, such as N-methylformamide, N, N-dimethylformamide, N, N-diethylformamide, acetamide, N-methylacetamide, N, N-dimethylacetamide, and N-methylpropionamide.

Examples of the ester-based solvent include:
monocarboxylate ester-based solvents, such as n-butyl acetate and ethyl lactate;
partially etherized polyhydric alcohol acetate-based solvents, such as diethylene glycol mono-n-butyl ether acetate, propylene glycol monomethyl ether acetate, and dipropylene glycol monomethyl ether acetate;
lactone-based solvents, such as Y-butyrolactone and valerolactone;
carbonate-based solvents, such as diethyl carbonate, ethylene carbonate, and propylene carbonate; and
polyvalent carboxylic acid diester-based solvents, such as propylene glycol diacetate, methoxy triglycol acetate, diethyl oxalate, ethyl acetoacetate, ethyl lactate, and diethyl phthalate.

Examples of the hydrocarbon-based solvent include:
aliphatic hydrocarbon-based solvents, such as n-hexane, cyclohexane, and methylcyclohexane; and
aromatic hydrocarbon-based solvents, such as benzene, toluene, di-iso-propylbenzene, and n-amylnaphthalene.

Among them, the ether-based solvents and the ester-based solvents are preferable, the partially etherized polyhydric alcohol-based solvents and the partially etherized polyhydric alcohol acetate-based solvents are more preferable, and propylene glycol monomethyl ether acetate, propylene glycol monomethyl ether, γ-butyrolactone, diacetone alcohol, ethyl lactate, and methyl 2-hydroxyisobutyrate are still more preferable. The radiation-sensitive resin composition may include one type of the solvent, or two or more types of the solvents in combination.

### <Other Optional Components>

The radiation-sensitive resin composition may contain other optional components in addition to the components described above. Examples of such other optional component may include a crosslinking agent, a localization enhancing agent, a surfactant, an alicyclic backbone-containing compound, and a sensitizer. These other optional components may be used singly, or two or more thereof may be used in combination.

### <Method for Preparing Radiation-Sensitive Resin Composition>

The radiation-sensitive resin composition described above can be prepared, for example, by mixing an onium salt, a base resin, a solvent, the radiation-sensitive onium salt (A) and the radiation-sensitive onium salt (B), and other optional components, as necessary, at a prescribed ratio. The radiation-sensitive resin composition is preferably filtered through, for example, a filter having a pore diameter of about 0.05 μm to 0.4 μm after mixing. The solid concentration of the radiation-sensitive resin composition is usually from 0.1% by mass to 50% by mass, preferably from 0.5% by mass to 30% by mass, and more preferably from 1% by mass to 20% by mass.

### <<Pattern Formation Method>>

A pattern formation method in the present embodiment includes:
step (1) of applying the radiation-sensitive resin composition directly or indirectly to a substrate to form a resist film (hereinafter, also referred to as “resist film forming step”);
step (2) of exposing the resist film to light (hereinafter, also referred to as “exposure step”); and
step (3) of developing the exposed resist film (hereinafter, also referred to as “development step”).

In accordance with this pattern formation method, a high-quality resist pattern can be formed because of the use of the radiation-sensitive resin composition superior in sensitivity and CDU performance in the exposure step. Hereinbelow, each of the steps will be described.

### [Resist Film Forming Step]

In this step (the step (1)), a resist film is formed of the radiation-sensitive resin composition. Examples of the substrate on which the resist film is formed include conventionally known substrates such as a silicon wafer, silicon dioxide, and a wafer coated with aluminum. An organic or inorganic antireflective film disclosed in, for example, JP-B-6-12452 or JP-A-59-93448 may be formed on the substrate. Examples of an applicating method include a rotary coating (spin coating), flow casting, and roll coating. After the application, prebaking (PB) may be performed to volatilize the solvent in the coating film, as necessary. The PB temperature is usually 60° C. to 150° C., and preferably 80° C. to 140° C. The PB duration is usually 5 seconds to 600 seconds, and preferably 10 seconds to 300 seconds. The thickness of the resist film to be formed is preferably 10 nm to 1,000 nm, and more preferably 10 nm to 500 nm.

When the exposure step, which is the next step, is performed with radiation having a wavelength of 50 nm or less, it is preferable to use, as the base resin in the composition, a resin containing the structural units (I) and (II), and the structural unit (III) as necessary.

### [Exposure Step]

In this step (the step (2)), the resist film formed in the resist film forming step, namely the step (1), is exposed to light by irradiation with radiation through a photomask (in some cases, through an immersion medium such as water). Examples of the radiation to be used for the exposure include an electromagnetic wave such as a visible ray, an ultraviolet ray, a far ultraviolet ray, an extreme ultraviolet ray (EUV), an X ray, or a γ ray; and a charged particle radiation such as an electron beam or an x ray, which may be chosen according to the line width of the target pattern. Among them, a far ultraviolet ray, an electron beam, or an EUV is preferable. ArF excimer laser light (wavelength is 193 nm), KrF excimer laser light (wavelength is 248 nm), an electron beam, or an EUV is more preferable. An electron beam having a wavelength of 50 nm or less, which is identified as the next generation exposing technology, or an EUV is further preferable.

After the exposure, post exposure baking (PEB) is preferably performed to promote the dissociation of the acid-dissociable group of the resin or the like due to the acid generated from the radiation-sensitive acid generator through exposure to light in the exposed area of the resist film. This PEB causes a difference in solubility in the developer between an exposed area and an unexposed area. The PEB temperature is usually 50° C. to 180° C., and preferably 80° C. to 130° C. The PEB duration is usually 5 seconds to 600 seconds, and preferably 10 seconds to 300 seconds.

### [Development Step]

In this step (the step (3)), the resist film exposed in the exposure step, namely the step (2), is developed. Thereby, a prescribed resist pattern can be formed. After the development, the resist pattern is generally washed with a rinse solution such as water or alcohol, and then dried.

Examples of the developer to be used for the development may include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, an aqueous TMAH solution is preferable, and a 2.38% by mass aqueous TMAH solution is more preferable.

In the case of organic solvent development, examples of the solvent include organic solvents such as hydrocarbon-based solvents, ether-based solvents, ester-based solvents, ketone-based solvents, and alcohol-based solvents, and solvents containing an organic solvent. Examples of the organic solvent include one type or two or more types of solvent among the solvents listed as the solvent for the radiation-sensitive resin composition. Among them, the ester-based solvent and the ketone-based solvent are preferable. As the ester-based solvent, acetate-based solvents are preferable, and n-butyl acetate and amyl acetate are more preferable. As the ketone-based solvent, chain ketones are preferable, and 2-heptanone is more preferable. The content of the organic solvent in the developer is preferably 80% by mass or more, more preferably 90% by mass or more, still more preferably 95% by mass or more, and particularly preferably 99% by mass or more. Examples of the component other than the organic solvent in the developer include water and silicone oil.

Examples of the developing method include a method including immersing a substrate in a tank filled with a developer for a given time (dipping method); a developing method including raising a developer on the surface of a substrate due to surface tension and leaving the raised developer at rest for a given time (paddling method); a method including spraying a developer to the surface of a substrate (spraying method); and a method including continuously ejecting a developer onto a substrate rotating at a constant rate while scanning a developer ejection nozzle at a constant rate (dynamic dispensing method).

### EXAMPLES

Hereinafter, the present invention will be specifically described with reference to Examples, but the present invention is not limited to these Examples. Physical property values in the Examples were measured as follows.

### [Weight-Average Molecular Weight (Mw) and Number-Average Molecular Weight (Mn)]

Measurement was performed by gel permeation chromatography (GPC) with monodisperse polystyrene standards using GPC columns (G2000HXL×2, G3000HXL×1, and G4000HXL×1) manufactured by Tosoh Corporation, under analysis conditions including a flow rate: 1.0 mL/min, an elution solvent: tetrahydrofuran, a sample concentration: 1.0 mass %, an amount of sample injected: 100 μL, a column temperature: 40° C., and a detector: a differential refractometer. The degree of dispersion (Mw/Mn) was calculated from the measurement results of Mw and Mn.

### <Synthesis of Photoacid Generator [A] and Photoacid Generator [B]>

### Synthesis Example 1: Synthesis of Compound (A-1)

Compound (A-1) was synthesized in accordance with the following reaction scheme.

Compound (P-1) (20 mmol), 4-acetylbenzoic acid (30 mmol), and p-toluenesulfonic acid monohydrate (4 mmol) were added to a vessel containing toluene (100 mL). The mixture was heated and refluxed for 3 hours while draining water with a Dean-Stark apparatus. The temperature was returned to room temperature, and ethyl acetate was added. The organic layer was washed twice with an aqueous sodium bicarbonate solution. The organic layer was dried over sodium sulfate and then filtered. The solvent was distilled off to yield a Compound (A-1).

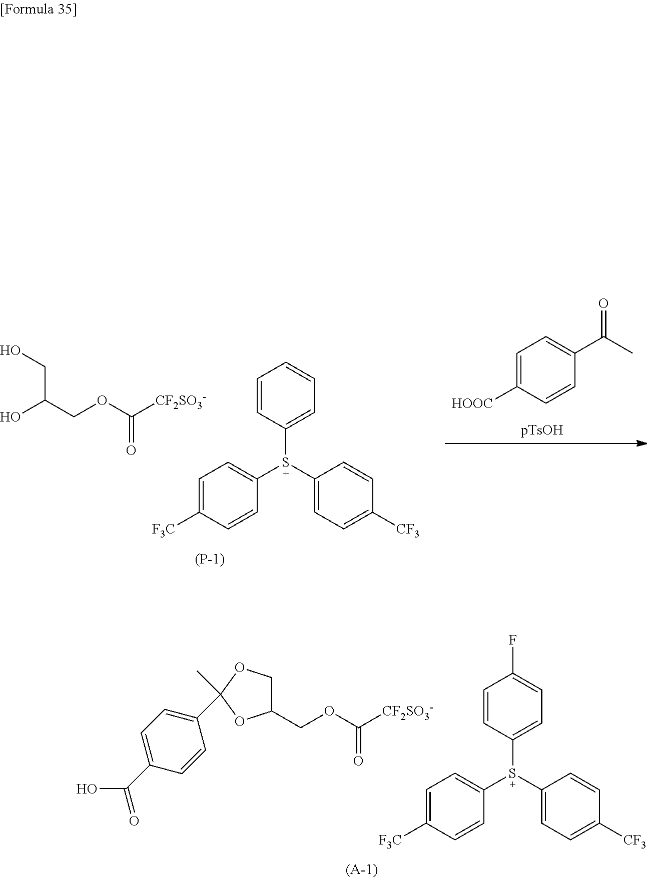

### Synthesis Examples 2 to 26: Synthesis of Compounds (A-2) to (A-12) and (B-1) to (B-14)

A precursor was appropriately selected, and the same formulation as that of Synthesis Example 1 was selected, whereby the photoacid generator [A] and the photoacid generator [B] represented by the following formulas (A-2) to (A-12) and (B-1) to (B-14) were synthesized. The photoacid generators [B] represented by the following formulas (B-11) and (B-12) were synthesized by a known method.

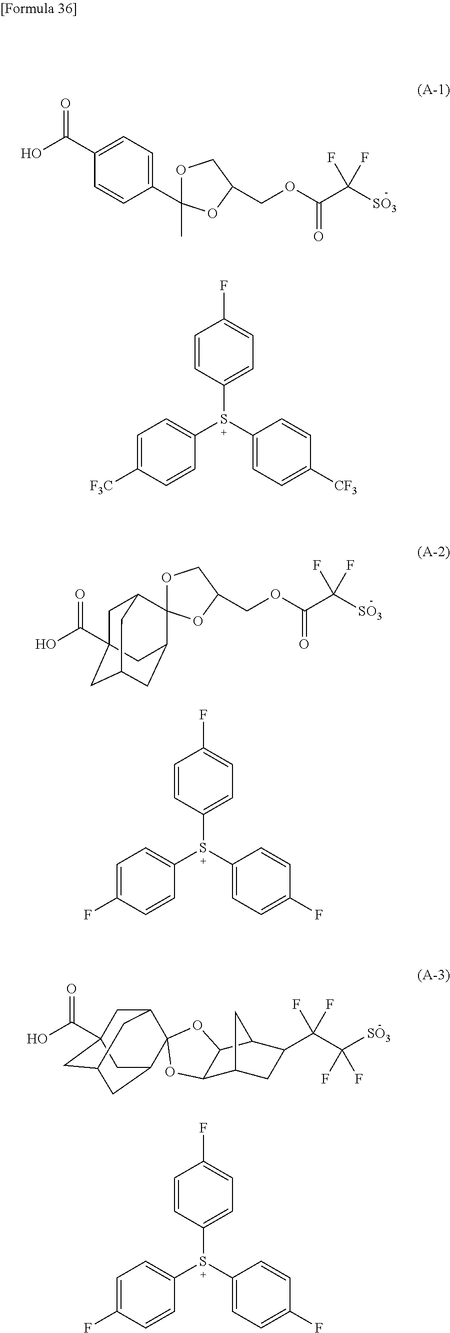

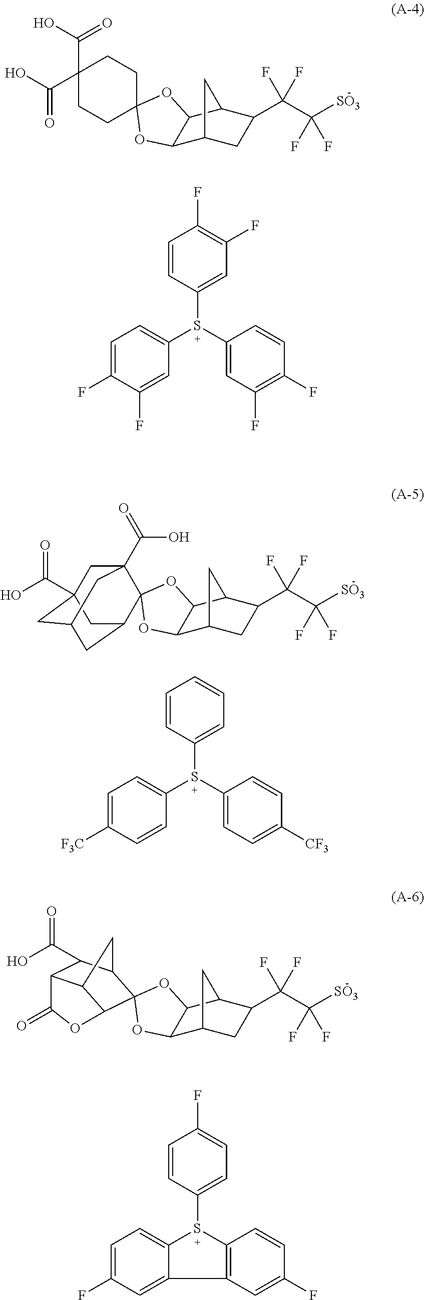

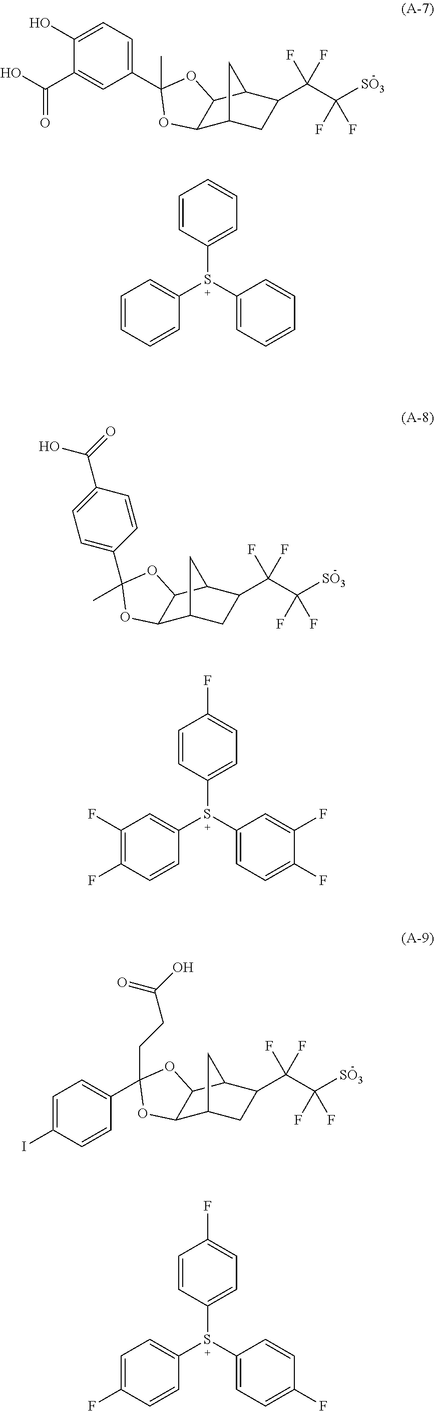

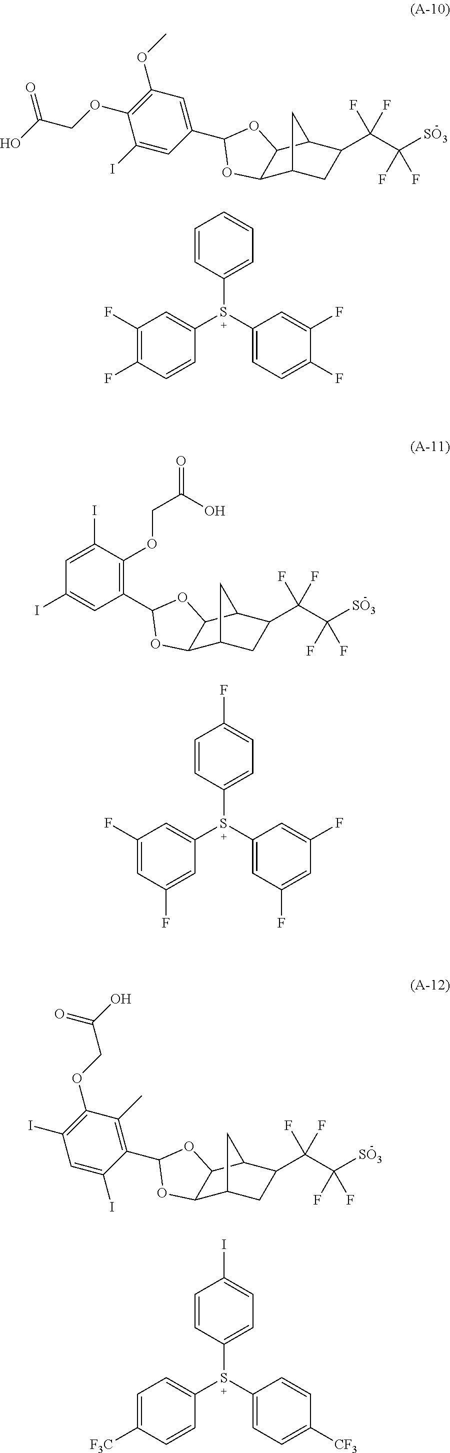

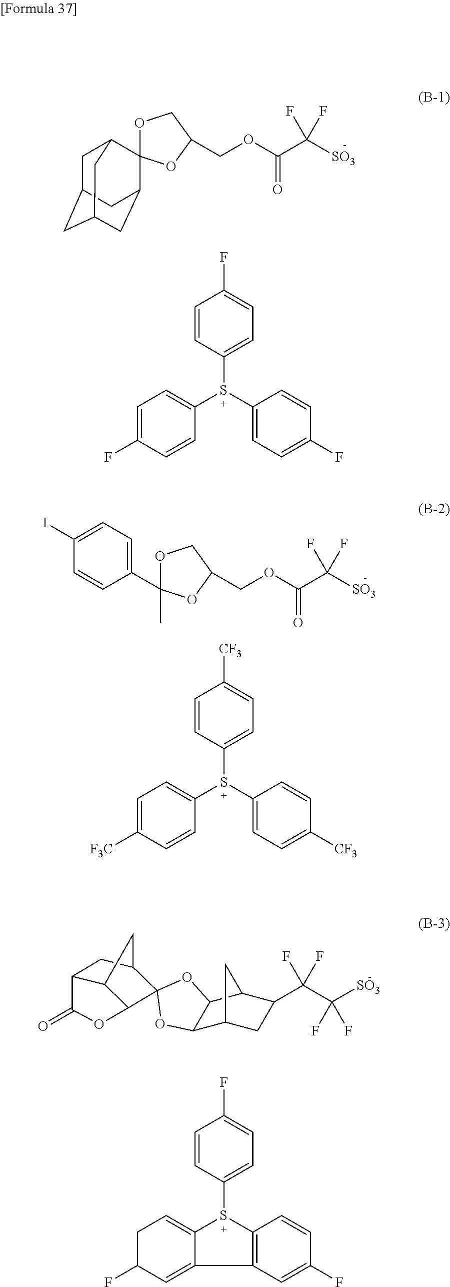

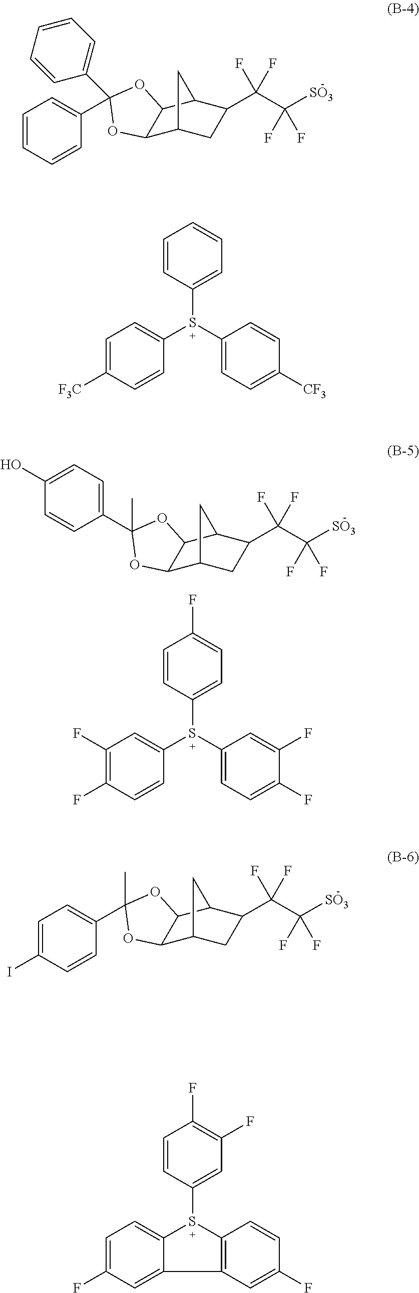

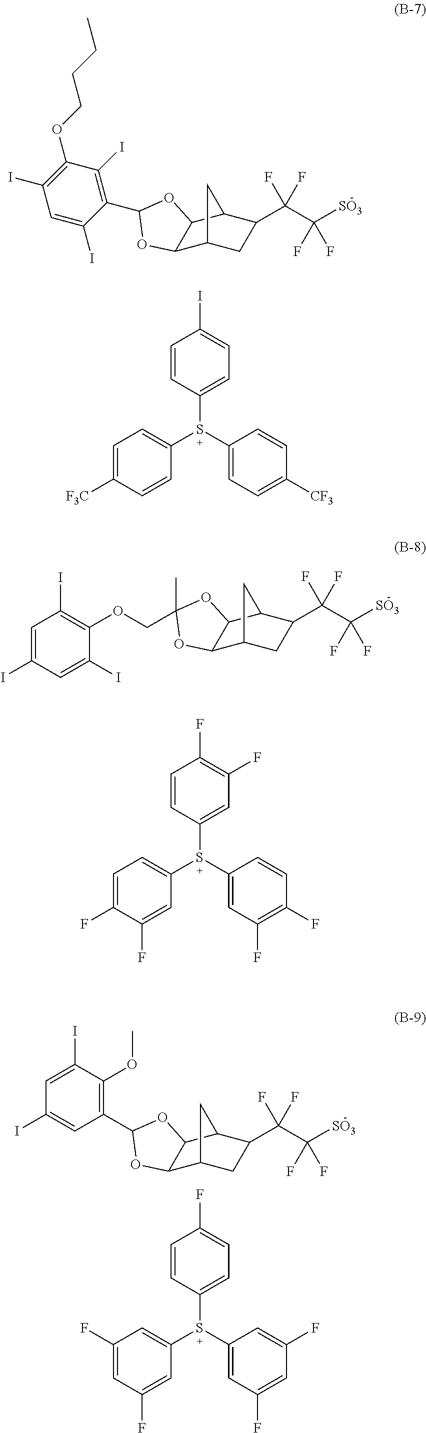

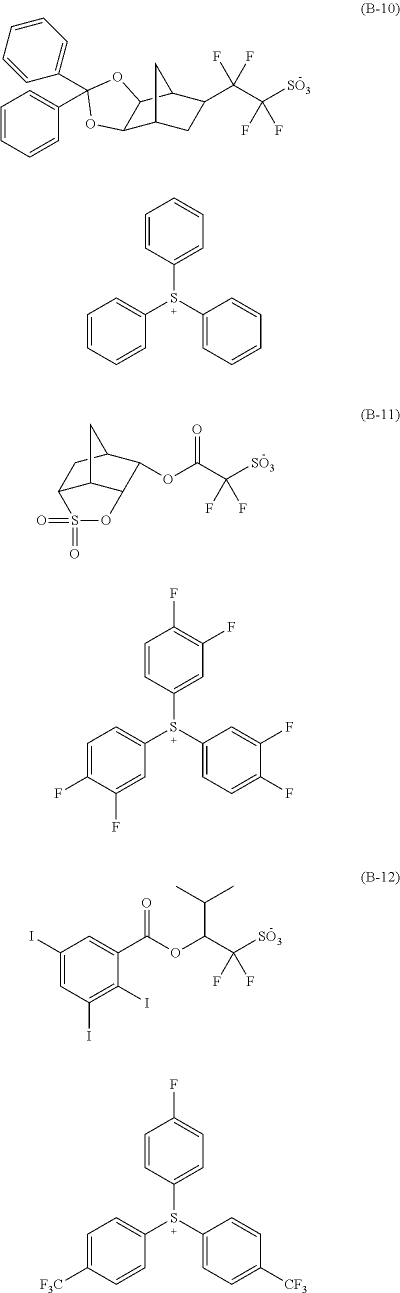

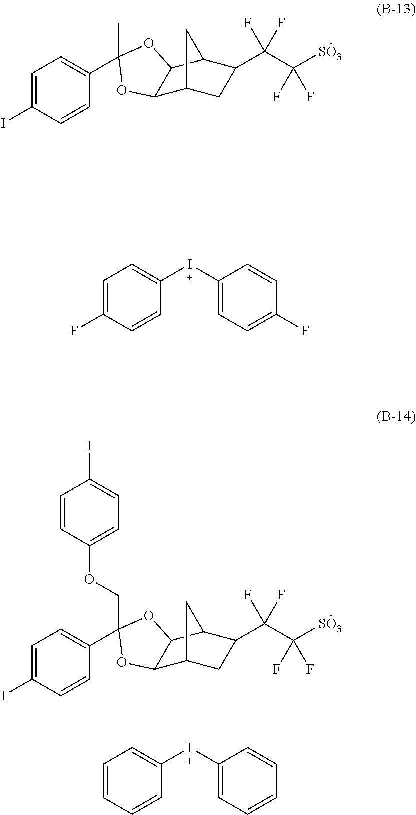

### <Synthesis of Polymer [C]>

The monomers used for the synthesis of the respective polymers in the respective Examples and Comparative Examples are shown below. In the following synthesis examples, unless otherwise specified, “parts by mass” means a value taken when the total mass of the monomers used is 100 parts by mass, and “mol %” means a value taken when the total number of moles of the monomers used is 100 mol %.

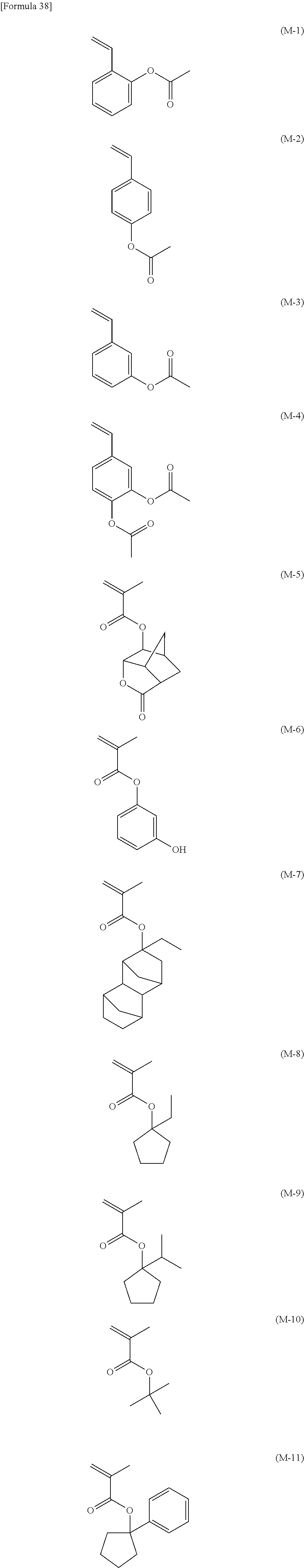

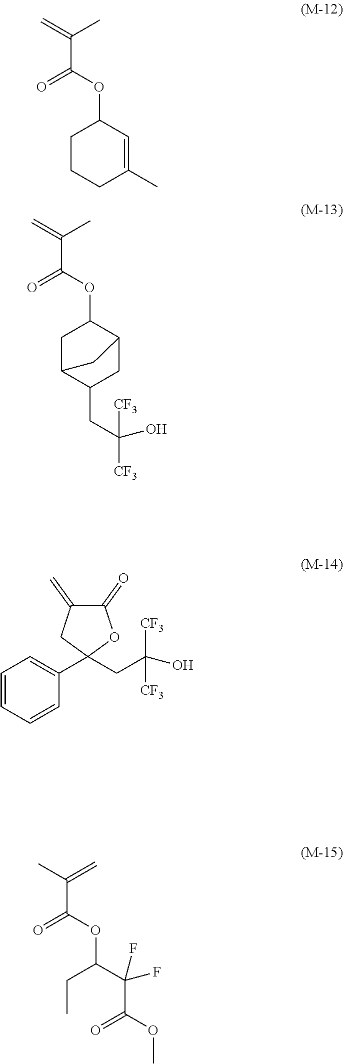

### Polymer Synthesis Example 1: Synthesis of Polymer (C-1)

Compounds (M-2) and (M-8) were dissolved in propylene glycol monomethyl ether (200 parts by mass) so as to have a molar ratio of 40/60. To this was added 2,2′-azobis(methyl isobutyrate) (10 mol % based on the total amount of monomers) as an initiator, whereby a monomer solution was prepared. Meanwhile, propylene glycol monomethyl ether (100 parts by mass based on the total amount of monomers) was added to an empty reaction vessel, and was heated to 85° C. with stirring. Next, the monomer solution prepared above was added dropwise over 3 hours, followed by further heating at 85° C. for 3 hours. After completion of the polymerization reaction, the polymerization solution was cooled to room temperature. The polymerization solution was added dropwise to n-hexane (1,000 parts by mass), whereby the polymer was coagulated and purified. To the polymer collected were added propylene glycol monomethyl ether (150 parts by mass), methanol (150 parts by mass), triethylamine (1.5 molar equivalent based on the use amount of Compound (M-2)), and water (1.5 molar equivalent based on the use amount of Compound (M-2)). A hydrolysis reaction was carried out for 8 hours while refluxing at a boiling point. After completion of the reaction, the solvent and triethylamine were distilled off under reduced pressure. The resulting polymer was dissolved in acetone (150 parts by mass). The solution was added dropwise to water (2,000 parts by mass) for coagulation. The generated white powder was collected. The resultant was dried at 50° C. for 17 hours, affording a white powdery Polymer (C-1) in good yield.

### Polymer Synthesis Examples 2 to 16: Synthesis of Polymers (C-2) to (C-16)

Polymers (C-2) to (C-16) were synthesized by appropriately selecting monomers and performing the same operations as in Polymer Synthesis Example 1.

The used amounts of the respective structural units, the values of Mw and Mw/Mn of the obtained polymers are shown in Table 1.

TABLE 1

| | | MONOMER | | MONOMER | | MONOMER | | | |
|---|---|---|---|---|---|---|---|---|---|
| | | THAT AFFORDS | | THAT AFFORDS | | THAT AFFORDS | | | |
| | | STRUCTURAL | | STRUCTURAL | | STRUCTURAL | | | |
| | | UNIT (I) | | UNIT (II) | | UNIT (III) | | | |
| | | | USED | | USED | | USED | | |
| | POLYMER | | AMOUNT | | AMOUNT | | AMOUNT | | |
| | [C] | TYPE | (mol %) | TYPE | (mol %) | TYPE | (mol %) | Mw | Mw/Mn |
| POLYMER | C-1 | M-2 | 40 | M-8 | 60 | — | — | 5,800 | 1.5 |
| SYNTHESIS | | | | | | | | | |
| EXAMPLE 1 | | | | | | | | | |
| POLYMER | C-2 | M-2 | 40 | M-7 | 60 | — | — | 5,900 | 1.5 |
| SYNTHESIS | | | | | | | | | |
| EXAMPLE 2 | | | | | | | | | |
| POLYMER | C-3 | M-2 | 40 | M-9 | 60 | — | — | 6,100 | 1.6 |
| SYNTHESIS | | | | | | | | | |
| EXAMPLE 3 | | | | | | | | | |
| POLYMER | C-4 | M-2 | 40 | M-9/M-10 | 50/10 | — | — | 6,500 | 1.6 |
| SYNTHESIS | | | | | | | | | |
| EXAMPLE 4 | | | | | | | | | |
| POLYMER | C-5 | M-2 | 40 | M-11 | 60 | — | — | 6,000 | 1.7 |
| SYNTHESIS | | | | | | | | | |
| EXAMPLE 5 | | | | | | | | | |
| POLYMER | C-6 | M-2 | 40 | M-12 | 60 | — | — | 6,300 | 1.5 |
| SYNTHESIS | | | | | | | | | |
| EXAMPLE 6 | | | | | | | | | |
| POLYMER | C-7 | M-2 | 45 | M-9 | 55 | — | — | 6,200 | 1.4 |
| SYNTHESIS | | | | | | | | | |
| EXAMPLE 7 | | | | | | | | | |
| POLYMER | C-8 | M-2 | 50 | M-9 | 50 | — | — | 5,900 | 1.4 |
| SYNTHESIS | | | | | | | | | |
| EXAMPLE 8 | | | | | | | | | |
| POLYMER | C-9 | M-2 | 55 | M-9 | 45 | — | — | 5,500 | 1.4 |
| SYNTHESIS | | | | | | | | | |
| EXAMPLE 9 | | | | | | | | | |
| POLYMER | C-10 | M-2/M-3 | 20/20 | M-8 | 60 | — | — | 5,500 | 1.6 |
| SYNTHESIS | | | | | | | | | |
| EXAMPLE 10 | | | | | | | | | |
| POLYMER | C-11 | M-2/M-1 | 20/20 | M-8 | 60 | — | — | 5,500 | 1.7 |
| SYNTHESIS | | | | | | | | | |
| EXAMPLE 11 | | | | | | | | | |
| POLYMER | C-12 | M-2/M-4 | 20/20 | M-8 | 60 | — | — | 5,800 | 1.5 |
| SYNTHESIS | | | | | | | | | |
| EXAMPLE 12 | | | | | | | | | |
| POLYMER | C-13 | M-2 | 20 | M-8 | 60 | M-5 | 20 | 5,900 | 1.6 |
| SYNTHESIS | | | | | | | | | |
| EXAMPLE 13 | | | | | | | | | |
| POLYMER | C-14 | M-2/M-6 | 20/20 | M-8 | 60 | — | — | 6,000 | 1.5 |
| SYNTHESIS | | | | | | | | | |
| EXAMPLE 14 | | | | | | | | | |
| POLYMER | C-15 | M-2 | 20 | M-8 | 60 | M-13 | 20 | 6,100 | 1.4 |
| SYNTHESIS | | | | | | | | | |
| EXAMPLE 15 | | | | | | | | | |
| POLYMER | C-16 | M-2 | 20 | M-8 | 60 | M-14 | 20 | 6,200 | 1.6 |
| SYNTHESIS | | | | | | | | | |
| EXAMPLE 16 | | | | | | | | | |

### Polymer Synthesis Example 17: Synthesis of Polymer (T-1)

Compounds (M-9) and (M-15) were dissolved in 2-butanone (100 parts by mass based on the total amount of monomers) such that the molar ratio was 40/60. To this was added azobisisobutyronitrile (5 mol % based on the total amount of monomers) as an initiator, whereby a monomer solution was prepared. Meanwhile, 2-butanone (50 parts by mass) was placed in an empty vessel, followed by purge with nitrogen for 30 minutes. The inside of the vessel was heated to 80° C., and the monomer solution was added dropwise thereto over 3 hours with stirring. After completion of the dropwise addition, the mixture was further heated at 80° C. for 3 hours, and then the polymerization solution was cooled to 30° C. or lower. The polymerization solution was transferred to a separatory funnel, followed by addition of hexane (150 parts by mass) to dilute the polymerization solution uniformly. Methanol (600 parts by mass) and water (30 parts by mass) were further charged, followed by mixing. After standing for 30 minutes, the lower layer was collected, and the solvent was replaced by propylene glycol monomethyl ether acetate. In this way, a 10% solution of Polymer (T-1) in propylene glycol monomethyl ether acetate was obtained. The polymer (T-1) had Mw=7, 200 and Mw/Mn=1.7.

### <Preparation of Radiation-Sensitive Resin Composition>

The photoacid generators [A], the photoacid generators [B], the acid diffusion controlling agents [D], and the organic solvents [E] used for the preparation of the radiation-sensitive resin compositions of the following Examples and Comparative Examples are shown below.

### Photoacid Generator [A] and Photoacid Generator [B]

Compounds represented by the above (A-1) to (A-12) and (B-1) to (B-14) were used as radiation-sensitive acid generators.

### Acid Diffusion Controlling Agent [D]

Compounds represented by the following (D-1) to (D-6) were used as acid diffusion controlling agents.

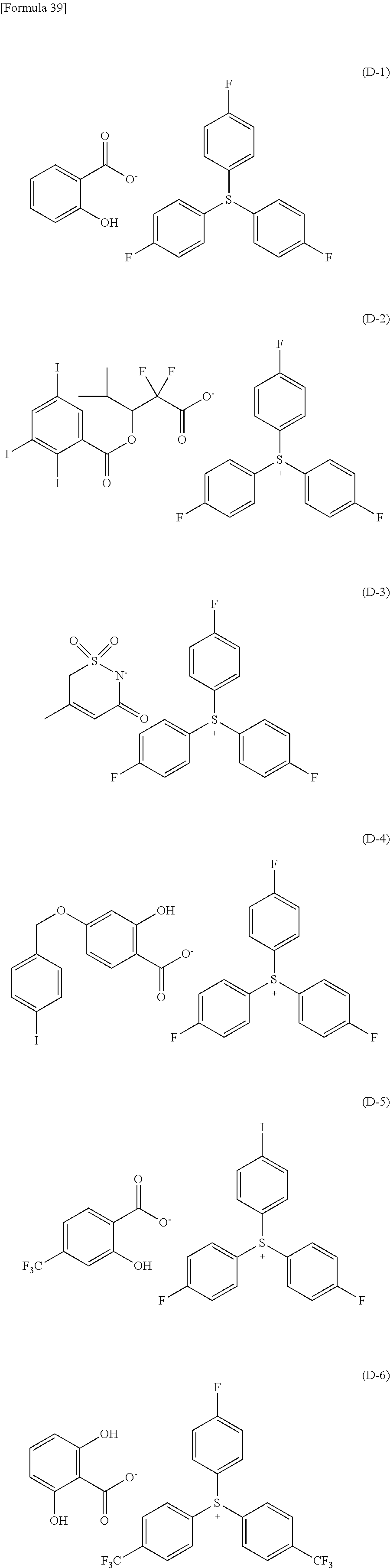

### Organic Solvent [E]

E-1: Propylene glycol monomethyl ether acetate
E-2: Propylene glycol monomethyl ether
E-3: Methyl 2-hydroxyisobutyrate

### Example 1

[C] 100 parts by mass of polymer (C-1), [T] 3 parts by mass in solid content of polymer (T-1), [A] 10 parts by mass of photoacid generator (A-1), [B] 40 parts by mass of photoacid generator (B-6), [D] acid diffusion controlling agent (D-1) in an amount of 35 mol % based on the total of (A-1) and (B-6), and [E] 1,500 parts by mass of (E-1) and 6,200 parts by mass of (E-2) as organic solvents were blended. This mixture was filtered through a filter having a pore size of 0.2 μm, whereby radiation-sensitive resin composition (R-1) was prepared.

### Examples 2 to 55 and Comparative Examples 1 to 3

Radiation-sensitive resin compositions (R-2) to (R-55) and (CR-1) to (CR-3) were prepared in the same manner as in Example 1 except that the types and the blending amounts of respective components shown in the following Table 2 were used.

TABLE 2

| | | | | | | PHOTOACID | |
|---|---|---|---|---|---|---|---|
| | | POLYMER | | POLYMER | | GENERATOR | |
| | RADIATION- | [C] | | [T] | | [A] | |
| | SENSITIVE | | CONTENT | | CONTENT | | CONTENT |
| | RESIN | | (parts by | | (parts by | | (parts by |
| | COMPOSITION | TYPE | mass) | TYPE | mass) | TYPE | mass) |
| Example 1 | R-1 | C-1 | 100 | T-1 | 3 | A-1 | 10 |
| Example 2 | R-2 | C-1 | 100 | T-1 | 3 | A-2 | 10 |
| Example 3 | R-3 | C-1 | 100 | T-1 | 3 | A-3 | 10 |
| Example 4 | R-4 | C-1 | 100 | T-1 | 3 | A-4 | 10 |
| Example 5 | R-5 | C-1 | 100 | T-1 | 3 | A-5 | 10 |
| Example 6 | R-6 | C-1 | 100 | T-1 | 3 | A-6 | 10 |
| Example 7 | R-7 | C-1 | 100 | T-1 | 3 | A-7 | 10 |
| Example 8 | R-8 | C-1 | 100 | T-1 | 3 | A-8 | 10 |
| Example 9 | R-9 | C-1 | 100 | T-1 | 3 | A-9 | 10 |
| Example 10 | R-10 | C-1 | 100 | T-1 | 3 | A-10 | 10 |
| Example 11 | R-11 | C-1 | 100 | T-1 | 3 | A-11 | 10 |
| Example 12 | R-12 | C-1 | 100 | T-1 | 3 | A-12 | 10 |
| Example 13 | R-13 | C-1 | 100 | T-1 | 3 | A-1 | 10 |
| Example 14 | R-14 | C-1 | 100 | T-1 | 3 | A-1 | 10 |
| Example 15 | R-15 | C-1 | 100 | T-1 | 3 | A-1 | 10 |
| Example 16 | R-16 | C-1 | 100 | T-1 | 3 | A-1 | 10 |
| Example 17 | R-17 | C-1 | 100 | T-1 | 3 | A-1 | 10 |
| Example 18 | R-18 | C-1 | 100 | T-1 | 3 | A-1 | 10 |
| Example 19 | R-19 | C-1 | 100 | T-1 | 3 | A-1 | 10 |
| Example 20 | R-20 | C-1 | 100 | T-1 | 3 | A-1 | 10 |
| Example 21 | R-21 | C-1 | 100 | T-1 | 3 | A-4 | 10 |
| Example 22 | R-22 | C-1 | 100 | T-1 | 3 | A-5 | 10 |
| Example 23 | R-23 | C-1 | 100 | T-1 | 3 | A-7 | 10 |
| Example 24 | R-24 | C-1 | 100 | T-1 | 3 | A-9 | 10 |
| Example 25 | R-25 | C-1 | 100 | T-1 | 3 | A-10 | 10 |
| Example 26 | R-26 | C-1 | 100 | T-1 | 3 | A-11 | 10 |
| Example 27 | R-27 | C-1 | 100 | T-1 | 3 | A-12 | 10 |
| Example 28 | R-28 | C-1 | 100 | T-1 | 3 | A-11 | 10 |
| Example 29 | R-29 | C-1 | 100 | T-1 | 3 | A-11 | 10 |
| Example 30 | R-30 | C-1 | 100 | T-1 | 3 | A-11 | 10 |
| Example 31 | R-31 | C-1 | 100 | T-1 | 3 | A-12 | 25 |
| Example 32 | R-32 | C-1 | 100 | T-1 | 3 | A-12 | 40 |
| Example 33 | R-33 | C-2 | 100 | T-1 | 3 | A-8 | 10 |
| Example 34 | R-34 | C-3 | 100 | T-1 | 3 | A-8 | 10 |
| Example 35 | R-35 | C-4 | 100 | T-1 | 3 | A-8 | 10 |
| Example 36 | R-36 | C-5 | 100 | T-1 | 3 | A-8 | 10 |
| Example 37 | R-37 | C-6 | 100 | T-1 | 3 | A-8 | 10 |
| Example 38 | R-38 | C-7 | 100 | T-1 | 3 | A-8 | 10 |
| Example 39 | R-39 | C-8 | 100 | T-1 | 3 | A-8 | 10 |
| Example 40 | R-40 | C-9 | 100 | T-1 | 3 | A-8 | 10 |
| Example 41 | R-41 | C-10 | 100 | T-1 | 3 | A-8 | 10 |
| Example 42 | R-42 | C-11 | 100 | T-1 | 3 | A-8 | 10 |
| Example 43 | R-43 | C-12 | 100 | T-1 | 3 | A-8 | 10 |
| Example 44 | R-44 | C-13 | 100 | T-1 | 3 | A-8 | 10 |
| Example 45 | R-45 | C-14 | 100 | T-1 | 3 | A-8 | 10 |
| Example 46 | R-46 | C-15 | 100 | T-1 | 3 | A-8 | 10 |
| Example 47 | R-47 | C-16 | 100 | T-1 | 3 | A-8 | 10 |
| Example 48 | R-48 | C-1 | 100 | T-1 | 3 | A-8 | 10 |
| Example 49 | R-49 | C-1 | 100 | T-1 | 3 | A-8 | 10 |
| Example 50 | R-50 | C-1 | 100 | T-1 | 3 | A-8 | 10 |
| Example 51 | R-51 | C-1 | 100 | T-1 | 3 | A-8 | 10 |
| Example 52 | R-52 | C-1 | 100 | T-1 | 3 | A-8 | 10 |
| Example 53 | R-53 | C-1 | 100 | T-1 | 3 | A-1 | 10 |
| Example 54 | R-54 | C-1 | 100 | T-1 | 3 | A-1 | 10 |
| Example 55 | R-55 | C-1 | 100 | T-1 | 3 | A-1 | 10 |
| Comparative | CR-1 | C-1 | 100 | T-1 | 3 | A-8 | 50 |
| Example 1 | | | | | | | |
| Comparative | CR-2 | C-1 | 100 | T-1 | 3 | — | — |
| Example 2 | | | | | | | |
| Comparative | CR-3 | C-1 | 100 | T-1 | 3 | A-7 | 10 |
| Example 3 | | | | | | | |

| | PHOTOACID | | | | ORGANIC | |
|---|---|---|---|---|---|---|
| | GENERATOR | | ACID DIFFUSION | | SOLVENT | |
| | [B] | | CONTROLLING | | [E] | |
| | | CONTENT | AGENT [D] | | | CONTENT |
| | | (parts by | | CONTENT | | (parts by |
| | TYPE | mass) | TYPE | (mol %) | TYPE | mass) |
| Example 1 | B-6 | 40 | D-1 | 35 | E-1/E-2 | 1500/6200 |
| Example 2 | B-6 | 40 | D-1 | 35 | E-1/E-2 | 1500/6200 |
| Example 3 | B-6 | 40 | D-1 | 35 | E-1/E-2 | 1500/6200 |
| Example 4 | B-6 | 40 | D-1 | 35 | E-1/E-2 | 1500/6200 |
| Example 5 | B-6 | 40 | D-1 | 35 | E-1/E-2 | 1500/6200 |
| Example 6 | B-6 | 40 | D-1 | 35 | E-1/E-2 | 1500/6200 |
| Example 7 | B-6 | 40 | D-1 | 35 | E-1/E-2 | 1500/6200 |
| Example 8 | B-6 | 40 | D-1 | 35 | E-1/E-2 | 1500/6200 |
| Example 9 | B-6 | 40 | D-1 | 35 | E-1/E-2 | 1500/6200 |
| Example 10 | B-6 | 40 | D-1 | 35 | E-1/E-2 | 1500/6200 |
| Example 11 | B-6 | 40 | D-1 | 35 | E-1/E-2 | 1500/6200 |
| Example 12 | B-6 | 40 | D-1 | 35 | E-1/E-2 | 1500/6200 |
| Example 13 | B-1 | 40 | D-1 | 35 | E-1/E-2 | 1500/6200 |
| Example 14 | B-2 | 40 | D-1 | 35 | E-1/E-2 | 1500/6200 |
| Example 15 | B-3 | 40 | D-1 | 35 | E-1/E-2 | 1500/6200 |
| Example 16 | B-4 | 40 | D-1 | 35 | E-1/E-2 | 1500/6200 |
| Example 17 | B-5 | 40 | D-1 | 35 | E-1/E-2 | 1500/6200 |
| Example 18 | B-7 | 40 | D-1 | 35 | E-1/E-2 | 1500/6200 |
| Example 19 | B-8 | 40 | D-1 | 35 | E-1/E-2 | 1500/6200 |
| Example 20 | B-9 | 40 | D-1 | 35 | E-1/E-2 | 1500/6200 |
| Example 21 | B-7 | 40 | D-1 | 35 | E-1/E-2 | 1500/6200 |
| Example 22 | B-8 | 40 | D-1 | 35 | E-1/E-2 | 1500/6200 |
| Example 23 | B-9 | 40 | D-1 | 35 | E-1/E-2 | 1500/6200 |
| Example 24 | B-9 | 40 | D-1 | 35 | E-1/E-2 | 1500/6200 |
| Example 25 | B-7 | 40 | D-1 | 35 | E-1/E-2 | 1500/6200 |
| Example 26 | B-8 | 40 | D-1 | 35 | E-1/E-2 | 1500/6200 |
| Example 27 | B-9 | 40 | D-1 | 35 | E-1/E-2 | 1500/6200 |
| Example 28 | B-10 | 40 | D-1 | 35 | E-1/E-2 | 1500/6200 |
| Example 29 | B-11 | 40 | D-1 | 35 | E-1/E-2 | 1500/6200 |
| Example 30 | B-12 | 40 | D-1 | 35 | E-1/E-2 | 1500/6200 |
| Example 31 | B-9 | 25 | D-1 | 35 | E-1/E-2 | 1500/6200 |
| Example 32 | B-9 | 10 | D-1 | 35 | E-1/E-2 | 1500/6200 |
| Example 33 | B-6 | 40 | D-1 | 35 | E-1/E-2 | 1500/6200 |
| Example 34 | B-6 | 40 | D-1 | 35 | E-1/E-2 | 1500/6200 |
| Example 35 | B-6 | 40 | D-1 | 35 | E-1/E-2 | 1500/6200 |
| Example 36 | B-6 | 40 | D-1 | 35 | E-1/E-2 | 1500/6200 |
| Example 37 | B-6 | 40 | D-1 | 35 | E-1/E-2 | 1500/6200 |
| Example 38 | B-6 | 40 | D-1 | 35 | E-1/E-2 | 1500/6200 |
| Example 39 | B-6 | 40 | D-1 | 35 | E-1/E-2 | 1500/6200 |
| Example 40 | B-6 | 40 | D-1 | 35 | E-1/E-2 | 1500/6200 |
| Example 41 | B-6 | 40 | D-1 | 35 | E-1/E-2 | 1500/6200 |
| Example 42 | B-6 | 40 | D-1 | 35 | E-1/E-2 | 1500/6200 |
| Example 43 | B-6 | 40 | D-1 | 35 | E-1/E-2 | 1500/6200 |
| Example 44 | B-6 | 40 | D-1 | 35 | E-1/E-2 | 1500/6200 |
| Example 45 | B-6 | 40 | D-1 | 35 | E-1/E-2 | 1500/6200 |
| Example 46 | B-6 | 40 | D-1 | 35 | E-1/E-2 | 1500/6200 |
| Example 47 | B-6 | 40 | D-1 | 35 | E-1/E-2 | 1500/6200 |
| Example 48 | B-6 | 40 | D-2 | 35 | E-1/E-2 | 1500/6200 |
| Example 49 | B-6 | 40 | D-3 | 35 | E-1/E-2 | 1500/6200 |
| Example 50 | B-6 | 40 | D-4 | 35 | E-1/E-2 | 1500/6200 |
| Example 51 | B-6 | 40 | D-5 | 35 | E-1/E-2 | 1500/6200 |
| Example 52 | B-6 | 40 | D-6 | 35 | E-1/E-2 | 1500/6200 |
| Example 53 | B-6 | 40 | D-6 | 35 | E-1/E-2/E-3 | 1500/3100/3100 |
| Example 54 | B-13 | 40 | D-6 | 35 | E-1/E-2/E-3 | 1500/3100/3100 |
| Example 55 | B-14 | 40 | D-6 | 35 | E-1/E-2/E-3 | 1500/3100/3100 |
| Comparative | — | — | D-1 | 35 | E-1/E-2 | 1500/6200 |
| Example 1 | | | | | | |
| Comparative | B-6 | 50 | D-1 | 35 | E-1/E-2 | 1500/6200 |
| Example 2 | | | | | | |
| Comparative | B-10 | 50 | D-1 | 35 | E-1/E-2 | 1500/6200 |
| Example 3 | | | | | | |

### <Formation of Resist Pattern>

Each of the radiation-sensitive resin compositions prepared as described above was applied using a spin coater (CLEAN TRACK ACT12, manufactured by Tokyo Electron Ltd.) to a surface of a 12-inch silicon wafer with a 20 nm thick underlayer film (AL412, manufactured by Brewer Science). Soft baking (SB) was performed at 100° C. for 60 seconds, followed by cooling at 23° C. for 30 seconds, to form a resist film having a thickness of 40 nm. Then, the resist film was irradiated with EUV light using an EUV exposure machine (model “NXE3300”, manufactured by ASML, NA=0.33, lighting condition: Conventional, s=0.89). Then, the resist film was subjected to post exposure baking (PEB) at 100° C. for 60 seconds. Subsequently, development was performed at 23° C. for 30 seconds using a 2.38 wt % aqueous TMAH solution to form a positive-tone 50 nm-pitch 25 nm contact hole pattern.

### <Evaluation>

The sensitivity, CDU performance, and resolution of each of the radiation-sensitive resin compositions were evaluated by measuring each of the formed resist patterns in accordance with the following method. A scanning electron microscope (“CG-5000” manufactured by Hitachi High-Technologies Corporation) was used for measuring the length of the resist pattern. The evaluation results are shown in the following Table 3.

### [Sensitivity]

An exposure amount at which the 25 nm contact hole pattern was formed in the formation of the resist pattern was defined as an optimum exposure amount, and the optimum exposure amount was defined as sensitivity (mJ/cm²). The smaller the value is, the better the sensitivity is. The sensitivity was determined as “S” (extremely good) when the value was less than 56 mJ/cm², “A” (good) when the value was 56 mJ/cm² or more and less than 58 mJ/cm², “B” (slightly good) when the value was 58 mJ/cm² or more and 61 MJ/cm² or less, and “C” (poor) when the value was more than 61 mJ/cm².

### [CDU Performance]

The 25 nm contact hole pattern was observed from above using the scanning electron microscope, and a total of 800 arbitrary points were measured for the length. The dimensional variation (3σ) was determined and taken as the CDU performance (nm). The smaller the value of the CDU is, the smaller the variation in hole diameter in the long period is and the better the CDU performance is. The CDU performance was determined as “S” (extremely good) in the case of less than 3.4 nm, “A” (good) in the case of 3.4 nm or more and less than 3.6 nm, “B” (slightly good) in the case of 3.6 nm or more and less than 3.8 nm, and “C” (poor) in the case of 3.8 nm or more.

### [Storage Stability]

A radiation-sensitive resin composition was prepared, and then the radiation-sensitive resin composition was stored at −15° C. for 2 weeks or at 35° C. for 2 weeks. Thereafter, the sensitivity was determined in accordance with the sensitivity evaluation method described above. Based on the sensitivity of the radiation-sensitive resin composition stored at 15° C. for 2 weeks, when the sensitivity of the radiation-sensitive resin composition stored at 35° C. for 2 weeks was increased by 1% or more or decreased by 1% or more, the storage stability was determined as “poor”. Otherwise, the storage stability was determined as “good”.

TABLE 3

| | RADIATION- | | | |
|---|---|---|---|---|
| | SENSITIVE | | | |
| | RESIN | | | STORAGE |
| | COMPOSITION | SENSITIVITY | CDU | STABILITY |
| Example 1 | R-1 | A | A | GOOD |
| Example 2 | R-2 | A | A | GOOD |
| Example 3 | R-3 | A | A | GOOD |
| Example 4 | R-4 | A | A | GOOD |
| Example 5 | R-5 | A | A | GOOD |
| Example 6 | R-6 | A | A | GOOD |
| Example 7 | R-7 | A | A | GOOD |
| Example 8 | R-8 | A | A | GOOD |
| Example 9 | R-9 | S | A | GOOD |
| Example 10 | R-10 | S | A | GOOD |
| Example 11 | R-11 | S | A | GOOD |
| Example 12 | R-12 | S | A | GOOD |
| Example 13 | R-13 | B | B | GOOD |
| Example 14 | R-14 | A | A | GOOD |
| Example 15 | R-15 | B | B | GOOD |
| Example 16 | R-16 | B | B | GOOD |
| Example 17 | R-17 | B | B | GOOD |
| Example 18 | R-18 | B | A | GOOD |
| Example 19 | R-19 | A | A | GOOD |
| Example 20 | R-20 | A | A | GOOD |
| Example 21 | R-21 | S | S | GOOD |
| Example 22 | R-22 | S | S | GOOD |
| Example 23 | R-23 | S | S | GOOD |
| Example 24 | R-24 | S | S | GOOD |
| Example 25 | R-25 | S | S | GOOD |
| Example 26 | R-26 | S | S | GOOD |
| Example 27 | R-27 | S | S | GOOD |
| Example 28 | R-28 | B | B | GOOD |
| Example 29 | R-29 | B | B | GOOD |
| Example 30 | R-30 | A | B | GOOD |
| Example 31 | R-31 | S | A | GOOD |
| Example 32 | R-32 | A | A | GOOD |
| Example 33 | R-33 | A | A | GOOD |
| Example 34 | R-34 | A | A | GOOD |
| Example 35 | R-35 | A | A | GOOD |
| Example 36 | R-36 | A | A | GOOD |
| Example 37 | R-37 | A | A | GOOD |
| Example 38 | R-38 | A | A | GOOD |
| Example 39 | R-39 | S | A | GOOD |
| Example 40 | R-40 | S | B | GOOD |
| Example 41 | R-41 | A | A | GOOD |
| Example 42 | R-42 | A | A | GOOD |
| Example 43 | R-43 | A | A | GOOD |
| Example 44 | R-44 | A | A | GOOD |
| Example 45 | R-45 | A | A | GOOD |
| Example 46 | R-46 | A | A | GOOD |
| Example 47 | R-47 | A | A | GOOD |
| Example 48 | R-48 | A | A | GOOD |
| Example 49 | R-49 | B | B | GOOD |
| Example 50 | R-50 | A | A | GOOD |
| Example 51 | R-51 | A | A | GOOD |
| Example 52 | R-52 | A | A | GOOD |
| Example 53 | R-53 | A | A | GOOD |
| Example 54 | R-54 | S | A | GOOD |
| Example 55 | R-55 | S | A | GOOD |
| Comparative | C-1 | B | C | GOOD |
| Example 1 | | | | |
| Comparative | C-2 | A | A | POOR |
| Example 2 | | | | |
| Comparative | C-3 | C | C | GOOD |
| Example 3 | | | | |

### INDUSTRIAL APPLICABILITY

According to the radiation-sensitive resin composition and the resist pattern formation method of the present invention, sensitivity, CDU, and storage stability can be improved as compared with the conventional technology. Therefore, the radiation-sensitive composition and the pattern formation method can be suitably used for the formation of a fine resist pattern in a lithography process for various electronic devices such as semiconductor devices and liquid crystal devices.

1. A radiation-sensitive resin composition comprising:
a radiation-sensitive onium salt (A) represented by formula (1);
a radiation-sensitive onium salt (B) that is different from the radiation-sensitive onium salt (A) and is represented by formula (2);
a resin comprising a structural unit which comprises an acid-dissociable group; and
a solvent: 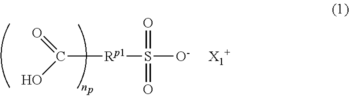
wherein, in the formula (1),
R^{p1} is a substituted or unsubstituted (nₚ+1)-valent hydrocarbon group having 1 to 20 carbon atoms, or a group comprising a divalent heteroatom-containing structure between adjacent two carbon atoms of a substituted or unsubstituted (nₚ+1)-valent hydrocarbon group having 1 to 20 carbon atoms the hydrocarbon group,
nₚ is an integer of 1 to 5, and
X₁⁺ is a monovalent radiation-sensitive onium cation, 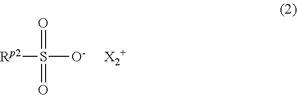
wherein, in the formula (2),
R^{p2} is a substituted or unsubstituted monovalent hydrocarbon group having 1 to 20 carbon atoms, and
X₂⁺ is a monovalent radiation-sensitive onium cation,
wherein at least one of X₁⁺ and X₂⁺ is a cation comprising a fluorine atom.

2. The radiation-sensitive resin composition according to claim 1, wherein at least one of X₁⁺ and X₂⁺ is represented by formula (3), 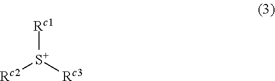
wherein, in the formula (3),
R^{c1} to R^{c3} are each independently a substituted or unsubstituted, linear or branched alkyl group having 1 to 12 carbon atoms or a substituted or unsubstituted aromatic hydrocarbon group having 6 to 12 carbon atoms, and at least one among R^{c1} to R^{c3} contains a fluorine atom or a trifluoromethyl group.

3. The radiation-sensitive resin composition according to claim 2, wherein R^{c1} to R^{c3} are each independently a substituted or unsubstituted aromatic hydrocarbon group having 6 to 12 carbon atoms.

4. The radiation-sensitive resin composition according to claim 1, wherein at least one of the radiation-sensitive onium salt (A) and the radiation-sensitive onium salt (B) contains an aromatic group substituted with an iodine atom.

5. The radiation-sensitive resin composition according to claim 1, wherein the radiation-sensitive onium salt (B) comprises no carboxyl group.

6. The radiation-sensitive resin composition according to claim 1, wherein at least one of X₁⁺ and X₂⁺ contains four or more fluorine atoms.

7. The radiation-sensitive resin composition according to claim 1, wherein a content of the radiation-sensitive onium salt (A) is 5 parts by mass or more and 45 parts by mass or less based on 100 parts by mass of the resin.

8. The radiation-sensitive resin composition according to claim 1, wherein a mass ratio of a content of the radiation-sensitive onium salt (A) to a content of the radiation-sensitive onium salt (B) (the content of the radiation-sensitive onium salt (A)/the content of the radiation-sensitive onium salt (B)) in the radiation-sensitive resin composition is 15/85 or more and 70/30 or less.

9. The radiation-sensitive resin composition according to claim 1, wherein the resin comprises a structural unit which comprises a phenolic hydroxy group.

10. The radiation-sensitive resin composition according to claim 1, further comprising an acid diffusion controlling agent.

11. A pattern formation method comprising:
applying the radiation-sensitive resin composition according to claim 1 directly or indirectly onto a substrate to form a resist film;
exposing the resist film to light; and
developing the exposed resist film with a developer.

12. The pattern formation method according to claim 11, wherein exposing comprises exposing the resist film to an extreme ultraviolet ray or an electron beam.
